(19) United States
(12) Patent Application Publication
(10) Pub. No.: US 2024/0196667 A1
(43) Pub. Date: Jun. 13, 2024

(54) DISPLAY DEVICE

(71) Applicant: LG DISPLAY CO., LTD., SEOUL (KR)

(72) Inventors: Yeonjun OH, Gimpo-si (KR); Chanwoo LEE, Seoul (KR)

(73) Assignee: LG DISPLAY CO., LTD., SEOUL (KR)

(21) Appl. No.: 18/387,077

(22) Filed: Nov. 6, 2023

(30) Foreign Application Priority Data
Dec. 9, 2022 (KR) 10-2022-0171715

(51) Int. Cl. H10K 59/124; G09G 3/3233; H10K 59/80

(52) U.S. Cl. CPC H10K 59/124; G09G 3/3233; H10K 59/873; G09G 2300/0842

(57) ABSTRACT

A display device includes a lower substrate which includes an active area including a plurality of sub pixels and a non-active area enclosing the active area and is formed of one of transparent conducting oxide and an oxide semiconductor layer, a rigid unit in the non-active area to enclose the active area on the lower substrate, an insulating layer on the lower substrate and the rigid unit, a cathode on the insulating layer, and an encapsulation substrate on the cathode. Accordingly, the rigid unit is disposed in an outer peripheral area of the display device to improve the rigidity of the outer peripheral area.

### CROSS-REFERENCE TO RELATED APPLICATION

This application claims the priority of Korean Patent Application No. 10-2022-0171715 filed on Dec. 9, 2022, which is hereby incorporated by reference in its entirety.

### BACKGROUND

### Field of the Disclosure

The present disclosure relates to a display device, and more particularly, to a display device with improved rigidity of an outer peripheral portion.

### Description of the Background

As display devices which are used for a monitor of a computer, a television, or a cellular phone, there are an organic light emitting display (OLED) device which is a self-emitting device and a liquid crystal display (LCD) device which requires a separate light source.

An applicable range of the display device is diversified to personal digital assistants as well as monitors of computers and televisions and a display device with a large display area and a reduced volume and weight is being studied.

Further, recently, a flexible display device which is manufactured by forming a display element and a wiring line on a flexible substrate, such as a plastic which is a flexible material, to be capable of displaying images even in a folded or rolled state is getting attention as a next generation display device.

### SUMMARY

Accordingly, the present disclosure is directed to a display device that substantially obviates one or more of problems due to limitations and disadvantages described above.

More specifically, the present disclosure is to provide a display device which uses one of a transparent conducting oxide layer and an oxide semiconductor layer as a substrate, instead of a plastic substrate.

Also, the present disclosure is to provide a display device with an improved rigidity of an outer peripheral area.

In addition, the present disclosure is to provide a display device which suppresses creases and cracks which may be generated in the outer peripheral area.

Further, the present disclosure is to provide a display device in which a parasitic capacitance by a rigid unit is minimized.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

The present disclosure is not limited to the above-mentioned and other features, which are not mentioned above, may be clearly understood by those skilled in the art from the following descriptions.

To achieve these and other advantages and in accordance with the present disclosure, as embodied and broadly described, a display device includes a lower substrate which includes an active area including a plurality of sub pixels and a non-active area enclosing the active area and is formed of one of transparent conducting oxide and an oxide semiconductor layer, a rigid unit which is in the non-active area on the lower substrate to enclose the active area, an insulating layer which is on the lower substrate and the rigid unit, a cathode on the insulating layer and an encapsulation substrate on the cathode.

In another aspect of the present disclosure, a display device includes a lower substrate which includes an active area and a non-active area and is formed of any one of transparent conducting oxide and an oxide semiconductor layer, a cathode in the active area on the lower substrate, an encapsulation substrate which covers the cathode and a plurality of rigid patterns which is on the lower substrate and is spaced apart from each other, wherein a first rigid pattern of the plurality of rigid patterns overlaps with an end of the cathode and a second rigid pattern of the plurality of rigid patterns overlaps with an end of the encapsulation substrate.

In a further aspect of the present disclosure, a display device includes a lower substrate which includes an active area including a plurality of sub pixels and a non-active area enclosing the active area and is formed of one of transparent conducting oxide and an oxide semiconductor layer, an insulating layer on the lower substrate, a cathode on the insulating layer and an encapsulation substrate on the cathode, wherein the cathode overlaps with an end of the encapsulation substrate.

Other detailed matters of the exemplary aspects are included in the detailed description and the drawings.

According to the present disclosure, a transparent conductive oxide layer and an oxide semiconductor layer are used as a substrate of the display device to easily control a moisture permeability and improve a flexibility.

According to the present disclosure, a rigid unit is disposed in an outer peripheral area to improve the rigidity of the outer peripheral area of the display device.

According to the present disclosure, the rigid unit is disposed to overlap with an end of a cathode and an end of an encapsulation unit to suppress the cracks and creases which may be generated during a manufacturing process.

According to the present disclosure, a plurality of rigid patterns is disposed to ensure the rigidity and minimize the parasitic capacitance.

According to the present disclosure, the rigid pattern is located in a corner area of the display device to suppress the increase of the parasitic capacitance and suppress the cracks generated when the display device is bent or rolled.

According to the present disclosure, a reinforcement unit is disposed at one side of the display device on the same layer as a lower substrate to suppress the cracks and creases which may be generated during the manufacturing process.

According to the present disclosure, the cathode is disposed to overlap with the end of the encapsulation substrate in a remaining area excluding one side of the display device to suppress the crack and the crease generated during the manufacturing process.

According to the present disclosure, a protection member is disposed below the lower substrate to suppress the generation of the crack.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a plan view of a display device according to an exemplary aspect of the present disclosure;

FIG. 2 is a schematic cross-sectional view of a display device according to an exemplary aspect of the present disclosure;

FIG. 3 is a circuit diagram of a sub pixel of a display device according to an exemplary aspect of the present disclosure;

FIG. 4 is an enlarged plan view of a display device according to an exemplary aspect of the present disclosure;

FIG. 5 is a cross-sectional view taken along line V-V′ of FIG. 4;

FIG. 6 is a cross-sectional view taken along line VI-VI′ of FIG. 1;

FIG. 7 is a cross-sectional view of a display device according to another exemplary aspect of the present disclosure;

FIG. 8 is a cross-sectional view of a display device according to still another exemplary aspect of the present disclosure;

FIG. 9 is a cross-sectional view of a display device according to still another exemplary aspect of the present disclosure;

FIG. 10 is a plan view of a display device according to still another exemplary aspect of the present disclosure;

FIG. 11 is a plan view of a display device according to still another exemplary aspect of the present disclosure;

FIG. 12 is a plan view of a display device according to still another exemplary aspect of the present disclosure;

FIG. 13 is a plan view of a display device according to still another exemplary aspect of the present disclosure;

FIG. 14 is a plan view of a display device according to still another exemplary aspect of the present disclosure;

FIG. 15 is a cross-sectional view taken along line XV-XV′ of FIG. 14; and

FIG. 16 is a cross-sectional view taken along line XVI-XVI′ of FIG. 14.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, a display device according to exemplary aspects of the present disclosure will be described in detail with reference to accompanying drawings.

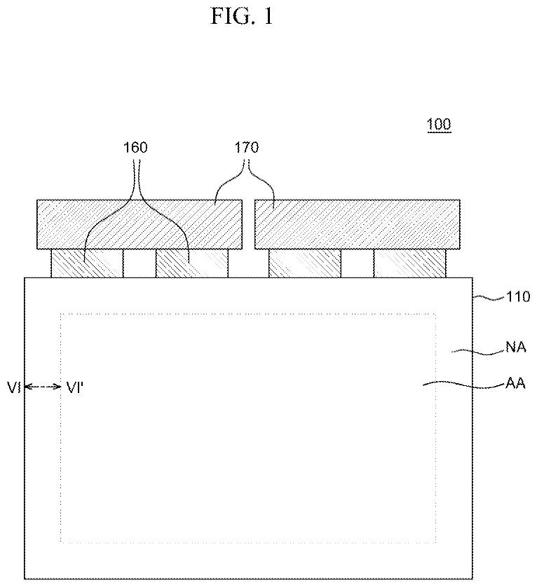

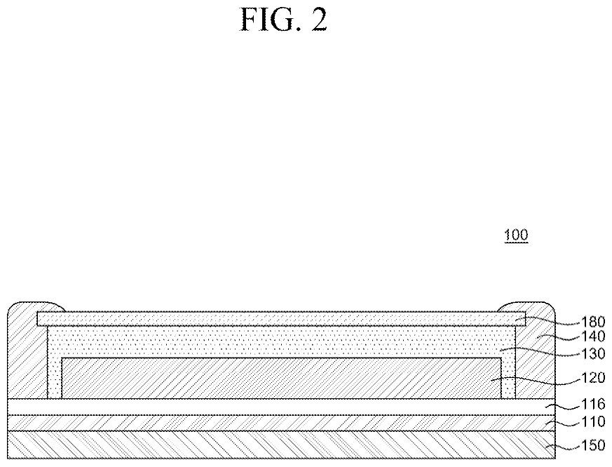

FIG. 1 is a plan view of a display device according to an exemplary aspect of the present disclosure. FIG. 2 is a schematic cross-sectional view of a display device according to an exemplary aspect of the present disclosure. For the convenience of description, in FIG. 1, among various components of the display device 100, only a lower substrate 110, a plurality of flexible films 160, and a plurality of printed circuit boards 170 are illustrated.

Referring to FIGS. 1 and 2, the lower substrate 110 is a support member which supports other components of the display device 100. The lower substrate 110 may be formed of any material that has sufficient rigidity. As an example, the lower substrate 110 may be formed of any one of a transparent conducting oxide and an oxide semiconductor. For example, the lower substrate 110 may be formed of a transparent conducting oxide (TCO), such as indium tin oxide (ITO), indium zinc oxide (IZO) and indium tin zinc oxide (ITZO). Embodiments are not limited thereto. As an example, the lower substrate 110 may be formed of inorganic materials such as glass, oxide materials or ceramics, etc. or organic materials such as polyimide (PI), polyethylene terephthalate (PET), acrylonitrile-butadiene-styrene copolymer (ABS), polymethyl methacrylate(PMMA), or polyethylene naphtha late (PEN), etc.

Further, the lower substrate 110 may be formed of an oxide semiconductor material formed of indium (In) and gallium (Ga), for example, a transparent oxide semiconductor such as indium gallium zinc oxide (IGZO), indium gallium oxide (IGO), and indium tin zinc oxide (ITZO). However, a type of a material of the transparent conducting oxide and the oxide semiconductor is illustrative so that the lower substrate 110 may be formed by another transparent conducting oxide and oxide semiconductor material which have not been described in the specification, but is not limited thereto.

In the meantime, the lower substrate 110 may be formed by depositing the transparent conducting oxide or an oxide semiconductor with a very thin thickness. Therefore, as the lower substrate 110 is formed to have a very thin thickness, the lower substrate may have a flexibility. Further, a display device 100 including the lower substrate 110 having a flexibility may be implemented as a flexible display device 100 which displays an image even in a folded or rolled state. For example, when the display device 100 is a foldable display device, the lower substrate 110 may be folded or unfolded with respect to a folding axis. As another example, when the display device 100 is a rollable display device, the display device may be stored by being rolled around the roller. Accordingly, the display device 100 according to the exemplary aspect of the present disclosure uses the lower substrate 110 having a flexibility to be implemented as a flexible display device 100 like a foldable display device or a rollable display device.

Further, the display device 100 according to the exemplary aspect of the present disclosure uses the lower substrate 110 formed of a transparent conducting oxide or an oxide semiconductor to perform a laser lift off (LLO) process. The LLO process refers to a process of separating a temporary substrate below the lower substrate 110 and the lower substrate 110 using laser during the manufacturing process of a display device 100. Accordingly, the lower substrate 110 is a layer for more easily performing the LLO process so that it is referred to as a functional thin film, a functional thin film layer, a functional substrate, or the like. The LLO process will be described in more detail below.

The lower substrate 110 includes an active area AA and a non-active area NA.

The active area AA is an area where images are displayed. In the active area AA, a pixel unit 120 configured by a plurality of sub pixels may be disposed to display images. For example, the pixel unit 120 is configured by a plurality of sub pixels including a light emitting diode and a driving circuit to display images.

The non-active area NA is an area where no image is displayed and various wiring lines and driving ICs for driving the sub pixels disposed in the active area AA are disposed. For example, in the non-active area NA, various driving ICs, such as a gate driver IC and a data driver IC, may be disposed.

The plurality of flexible films 160 is disposed at one end of the lower substrate 110. The plurality of flexible films 160 is electrically connected to one end of the lower substrate 110. The plurality of flexible films 160 is films in which various components are disposed on a base film having malleability to supply a signal to the plurality of sub pixels of the active area AA. One ends of the plurality of flexible films 160 are disposed in the non-active area NA of the lower substrate 110 to supply a signal such as a data voltage to the plurality of sub pixels of the active area AA. In the meantime, even though four flexible films 160 are illustrated in FIG. 1, the number of flexible films 160 may vary depending on the design, but is not limited thereto.

In the meantime, a driving IC such as a gate driver IC and a data driver IC may be disposed on the plurality of flexible films 160. The driving IC is a component which processes data for displaying images and a driving signal for processing the data. The driving IC may be disposed by a chip on glass (COG), a chip on film (COF), or a tape carrier package (TCP) technique depending on a mounting method. In the present specification, for the convenience of description, it is described that the driving IC is mounted on the plurality of flexible films 160 by a chip on film technique, but is not limited thereto.

The printed circuit board 170 is connected to the plurality of flexible films 160. The printed circuit board 170 is a component which supplies signals to the driving IC. Various components may be disposed in the printed circuit board 170 to supply various driving signals such as a driving signal and a data voltage to the driving IC. In the meantime, even though two printed circuit boards 170 are illustrated in FIG. 1, the number of printed circuit boards 170 may vary depending on the design and is not limited thereto.

Referring to FIG. 2, a lower buffer layer 116 is disposed on the lower substrate 110. The lower buffer layer 116 suppresses moisture and/or oxygen which penetrates from the outside of the lower substrate 110 from being spread. The moisture permeation characteristic of the display device 100 may be controlled by controlling a thickness or a lamination structure of the lower buffer layer 116. Further, the lower buffer layer 116 may suppress a short circuit problem caused when the lower substrate 110 formed of a transparent conducting oxide or an oxide semiconductor is in contact with the other configurations such as a pixel unit 120. The lower buffer layer 116 may be formed of an inorganic material, for example, may be configured by a single layer or a double layer or a multiple layer of silicon oxide SiOx and silicon nitride SiNx, but is not limited thereto.

The pixel unit 120 is disposed on the lower buffer layer 116. The pixel unit 120 may be disposed to correspond to the active area AA. The pixel unit 120 is a component which includes a plurality of sub pixels to display images. The plurality of sub pixels of the pixel unit 120 is minimum units which configure the active area AA and a light emitting diode and a driving circuit may be disposed in each of the plurality of sub pixels. For example, the light emitting diode of each of the plurality of sub pixels may include an organic light emitting diode including an anode, an organic emission layer, and a cathode or an LED including an N-type and a P-type semiconductor layers and an emission layer, but is not limited thereto. Further, the driving circuit for driving the plurality of sub pixels may include a driving element such as a thin film transistor and a storage capacitor, but is not limited thereto. Hereinafter, for the convenience of description, it is assumed that the light emitting diode of each of the plurality of sub pixels is an organic light emitting diode, but it is not limited thereto.

In the meantime, the display device 100 may be configured by a top emission type or a bottom emission type, depending on an emission direction of light which is emitted from the light emitting diode.

According to the top emission type, light emitted from the light emitting diode is emitted to an upper portion of the lower substrate 110 on which the light emitting diode is disposed. In the case of the top emission type, a reflective layer may be formed below the anode to allow the light emitted from the light emitting diode to travel to the upper portion of the lower substrate 110, that is, toward the cathode, without being limited thereto. As an example, the reflective layer may be omitted according to the design.

According to the bottom emission type, light emitted from the light emitting diode is emitted to a lower portion of the lower substrate 110 on which the light emitting diode is disposed. In the case of the bottom emission type, the anode may be formed only of a transparent conductive material and the cathode may be formed of the metal material having a high reflectance to allow the light emitted from the light emitting diode to travel to the lower portion of the lower substrate 110. Embodiments are not limited thereto. As an example, the anode may be also formed of a semitransparent conductive material or an opaque material, which for example may have a mesh shape, and/or the cathode may be formed of a material having no reflectance.

Hereinafter, for the convenience of description, the description will be made by assuming that the display device 100 according to an exemplary aspect of the present disclosure is a bottom emission type display device, but it is not limited thereto.

An encapsulation layer 130 is disposed to cover the pixel unit 120. The encapsulation layer 130 seals the pixel unit 120 to protect the light emitting diode of the pixel unit 120 from moisture, oxygen, and impacts of the outside. The encapsulation layer 130 may be configured by a face seal type. For example, the encapsulation layer 130 may be formed by forming ultraviolet or thermosetting sealant on the entire surface of the pixel unit 120. However, the structure of the encapsulation layer 130 may be formed by various methods and materials, but is not limited thereto.

An encapsulation substrate 180 may be disposed on the encapsulation layer 130. As an example, the encapsulation substrate 180 may have a high modulus and is formed of a metal material having a strong corrosion resistance, without being limited thereto. For example, the encapsulation substrate 180 may be formed of a material having a high modulus of approximately 200 to 900 MPa, without being limited thereto. As an example, the encapsulation substrate 180 may also be formed of a material having a modulus lower than 200 Mpa or higher than 900 MPa. The encapsulation substrate may be formed of a metal material, which has a high corrosion resistance and is easily processed in the form of a foil or a thin film, such as aluminum (Al), nickel (Ni), chromium (Cr), iron (Fe), and an alloy material of nickel. Therefore, as the encapsulation substrate 180 is formed of a metal material, the encapsulation substrate 180 may be implemented as an ultra-thin film and provide a strong resistance against external impacts and scratches.

A seal member 140 is disposed to enclose side surfaces of the pixel unit 120 and the encapsulation layer 130. The seal member 140 is disposed in the non-active area NA and may be disposed to enclose the pixel unit 120 disposed in the active area AA. The seal member 140 is disposed to enclose a side surface of the pixel unit 120 and a side surface of the encapsulation layer 130 to reduce or minimize the moisture permeation to the pixel unit 120. For example, the seal member 140 may be disposed to cover a top surface of the lower buffer layer 116 overlapping with a non-active area NA protruding to the outside of the pixel unit 120, a side surface of the encapsulation layer 130 disposed to enclose the pixel unit 120, and a part of a top surface of the encapsulation layer 130.

The seal member 140 may encapsulate the side surface of the pixel unit 120 and reinforce the rigidity of the side surface of the display device 100. As an example, the seal member 140 may be formed of a non-conducting material having an elasticity. Further, the seal member 140 may be formed of a material having an adhesiveness. Further, the seal member 140 may further include an absorbent which absorbs moisture and oxygen from the outside to reduce or minimize the moisture permeation through the side portion of the display device 100. For example, the seal member 140 may be formed of polyimide (PI), poly urethane, epoxy, or acryl based material, but is not limited thereto.

A polarizer 150 is disposed below the lower substrate 110. The polarizer 150 selectively transmits light to reduce the reflection of external light which is incident onto the lower substrate 110. Specifically, in the display device 100, various metal materials which are applied to semiconductor devices, wiring lines, and light emitting diodes is formed on the lower substrate 110. Therefore, the external light incident onto the lower substrate 110 may be reflected from the metal material so that the visibility of the display device 100 may be reduced due to the reflection of the external light. At this time, the polarizer 150 which suppresses the reflection of external light is disposed below the lower substrate 110 to increase outdoor visibility of the display device 100. However, the polarizer 150 may be omitted depending on an implementation example of the display device 100.

In the meantime, even though not illustrated in the drawing, a barrier film may be disposed below the lower substrate 110 together with the polarizer 150. The barrier film reduces or minimizes the permeation of the moisture and oxygen outside the lower substrate 110 into the lower substrate 110 to protect the pixel unit 120 including a light emitting diode. However, the barrier film may be omitted depending on an implementation example of the display device 100, but it is not limited thereto. Embodiments are not limited thereto. As an example, at least one of the above-mentioned components may be omitted, and/or at least one additional component may be further included.

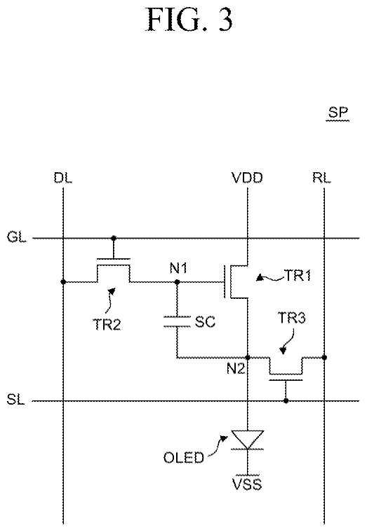

Hereinafter, the plurality of sub pixels of the pixel unit 120 will be described in more detail with reference to FIGS. 3 to 5.

FIG. 3 is a circuit diagram of a sub pixel of a display device according to an exemplary aspect of the present disclosure.

Referring to FIG. 3, the driving circuit for driving the light emitting diode OLED of the plurality of sub pixels SP includes a first transistor TR1, a second transistor TR2, a third transistor TR3, and a storage capacitor SC. Further, to drive the driving circuit, a plurality of wiring lines including a gate line GL, a data line DL, a high potential power line VDD, a sensing line SL, and a reference line RL is disposed on the lower substrate 110.

Each of the first transistor TR1, the second transistor TR2, and the third transistor TR3 included in the driving circuit of one sub pixel SP includes a gate electrode, a source electrode, and a drain electrode.

Further, the first transistor TR1, the second transistor TR2, and the third transistor TR3 may be P-type thin film transistors or N-type thin film transistors. For example, since in the P-type thin film transistor, holes flow from the source electrode to the drain electrode, the current may flow from the source electrode to the drain electrode. Since in the N-type thin film transistor, electrons flow from the source electrode to the drain electrode, the current may flow from the drain electrode to the source electrode. Hereinafter, the description will be made under the assumption that the first transistor TR1, the second transistor TR2, and the third transistor TR3 are N-type thin film transistors in which the current flows from the drain electrode to the source electrode, but the present disclosure is not limited thereto.

The first transistor TR1 includes a first active layer, a first gate electrode, a first source electrode, and a first drain electrode. The first gate electrode is connected to a first node N1, the first source electrode is connected to the anode of the light emitting diode OLED, and the first drain electrode is connected to the high potential power line VDD. When a voltage of the first node N1 is higher than a threshold voltage, the first transistor TR1 is turned on and when the voltage of the first node N1 is lower than the threshold voltage, the first transistor TR1 may be turned off. Further, when the first transistor TR1 is turned on, a driving current may be transmitted to the light emitting diode OLED by means of the first transistor TR1. Therefore, the first transistor TR1 which controls the driving current transmitted to the light emitting diode OLED may be referred to as a driving transistor.

The second transistor TR2 includes a second active layer, a second gate electrode, a second source electrode, and a second drain electrode. The second gate electrode is connected to the gate line GL, the second source electrode is connected to the first node N1, and the second drain electrode is connected to the data line DL. The second transistor TR2 may be turned on or off based on a gate voltage from the gate line GL. When the second transistor TR2 is turned on, a data voltage from the data line DL may be charged in the first node N1. Therefore, the second transistor TR2 which is turned on or turned off by the gate line GL may also be referred to as a switching transistor.

The third transistor TR3 includes a third active layer, a third gate electrode, a third source electrode, and a third drain electrode. The third gate electrode is connected to the sensing line SL, the third source electrode is connected to the second node N2, and the third drain electrode is connected to the reference line RL. The third transistor TR3 may be turned on or off based on a sensing voltage from the sensing line SL. Further, when the third transistor TR3 is turned on, a reference voltage from the reference line RL may be transmitted to the second node N2 and the storage capacitor SC. Therefore, the third transistor TR3 may also be referred to as a sensing transistor. As an example, the third transistor TR3, the reference line RL and/or the sensing line SL may be omitted, according to the design.

In the meantime, even though in FIG. 3, it is illustrated that the gate line GL and the sensing line SL are separate wiring lines, the gate line GL and the sensing line SL may be implemented as one wiring line, but it is not limited thereto.

The storage capacitor SC is connected between the first gate electrode and the first source electrode of the first transistor TR1. That is, the storage capacitor SC may be connected between the first node N1 and the second node N2. The storage capacitor SC maintains a potential difference between the first gate electrode and the first source electrode of the first transistor TR1 while the light emitting diode OLED emits light, so that a constant driving current may be supplied to the light emitting diode OLED. The storage capacitor SC includes a plurality of capacitor electrodes and for example, one of a plurality of capacitor electrodes is connected to the first node N1 and the other one may be connected to the second node N2.

The light emitting diode OLED includes an anode, an emission layer, and a cathode. The anode of the light emitting diode OLED is connected to the second node N2 and the cathode is connected to the low potential power line VSS. The light emitting diode OLED is supplied with a driving current from the first transistor TR1 to emit light.

In the meantime, in FIG. 3, it is described that the driving circuit of the sub pixel SP of the display device 100 according to the exemplary aspect of the present disclosure has a 3TIC structure including three transistors and one storage capacitor SC. However, the number and a connection relationship of the transistors and the storage capacitor may vary in various ways depending on the design and are not limited thereto.

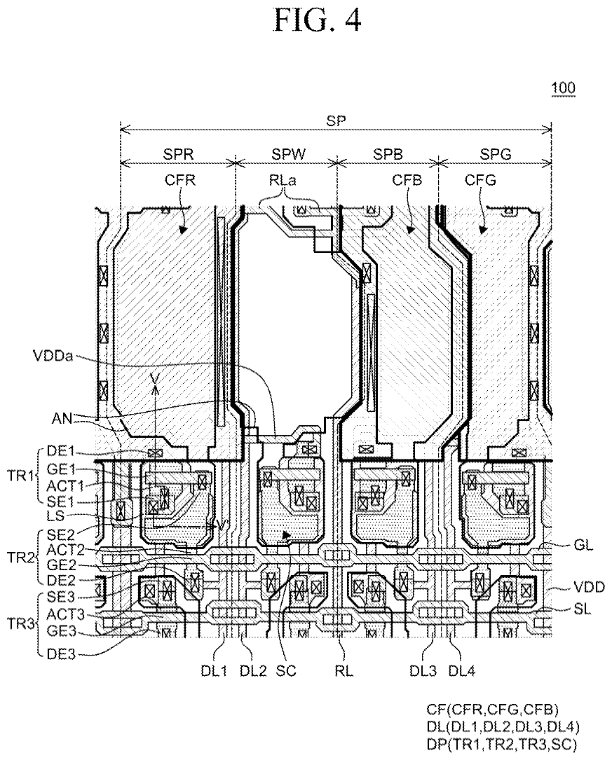

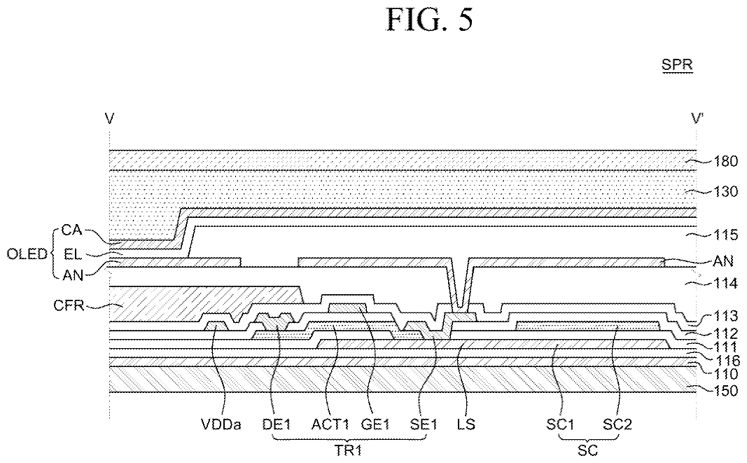

FIG. 4 is an enlarged plan view of a display device according to an exemplary aspect of the present disclosure. FIG. 5 is a cross-sectional view taken along line V-V′ of FIG. 4. FIG. 4 is an enlarged plan view of a red sub pixel SPR, a white sub pixel SPW, a blue sub pixel SPB, and a green sub pixel SPG which configure one pixel. In FIG. 4, for the convenience of description, the bank 115 is omitted and edges of the plurality of color filters CF are illustrated with a bold solid line. Referring to FIGS. 4 and 5, the display device 100 according to the exemplary aspect of the present disclosure includes a lower substrate 110, a lower buffer layer 116, an upper buffer layer 111, a gate insulating layer 112, a passivation layer 113, a planarization layer 114, a bank 115, a first transistor TR1, a second transistor TR2, a third transistor TR3, a storage capacitor SC, a light emitting diode OLED, a gate line GL, a sensing line SL, a data line DL, a reference line RL, a high potential power line VDD, and a plurality of color filters CF.

Referring to FIG. 4, the plurality of sub pixels SP includes a red sub pixel SPR, a green sub pixel SPG, a blue sub pixel SPB, and a white sub pixel SPW. For example, the red sub pixel SPR, the white sub pixel SPW, the blue sub pixel SPB, and the green sub pixel SPG may be sequentially disposed along a row direction. However, the placement order of the plurality of sub pixels SP is not limited thereto. As an example, sub pixels of other colors such as magenta, cyan and yellow, etc. may be included.

Each of the plurality of sub pixels SP includes an emission area and a circuit area. The emission area is an area where one color light is independently emitted and the light emitting diode OLED may be disposed therein. Specifically, in an area where the plurality of color filters CF and the anode AN overlap with each other, an area which is exposed from the bank 115 to allow light emitted from the light emitting diode OLED to travel to the outside may be defined as an emission area. For example, referring to FIGS. 4 and 5 together, an emission area of the red sub pixel SPR may be an area exposed from the bank 115 in an area in which the red color filter CFR and the anode AN overlap with each other. An emission area of the green sub pixel SPG may be an area exposed from the bank 115 in an area in which the green color filter CFG and the anode AN overlap with each other. An emission area of the blue sub pixel SPB is an area exposed from the bank 115 in an area in which the blue color filter CFB and the anode AN overlap with each other. An emission area of the blue sub pixel SPB may be a blue emission area which emits blue light. At this time, in an emission area of the white sub pixel SPW in which a separate color filter CF is not disposed, an area overlapping with a part of the anode AN exposed from the bank 115 may be a white emission area which emits white light.

The circuit area is a remaining area excluding the emission area and a driving circuit DP for driving the plurality of light emitting diodes OLED and a plurality of wiring lines which transmits various signals to the driving circuit DP may be disposed. Further, the circuit area in which the driving circuit DP, the plurality of wiring lines, the bank 115, and the like are disposed may be a non-emission area. For example, in the circuit area, the driving circuit DP including the first transistor TR1, the second transistor TR2, the third transistor TR3, and the storage capacitor SC, a plurality of high potential power lines VDD, a plurality of data lines DL, a plurality of reference lines RL, a plurality of gate lines GL, a sensing line SL, the bank 115, and the like may be disposed.

Referring to FIGS. 3 to 5, the lower buffer layer 116 is disposed on the lower substrate 110 and the plurality of high potential power line VDD, the plurality of data lines DL, the plurality of reference lines RL, and the light shielding layer LS are disposed on the lower buffer layer 116.

The plurality of high potential power lines VDD, the plurality of data lines DL, the plurality of reference lines RL, and the light shielding layer LS are disposed on the same layer on the lower substrate 110 and may be formed of the same conductive material. For example, the plurality of high potential power lines VDD, the plurality of data lines DL, the plurality of reference lines RL, and the light shielding layer LS may be configured by a conductive material, such as copper (Cu), aluminum (Al), molybdenum (Mo), nickel (Ni), titanium (Ti), and chrome (Cr), or an alloy thereof, but are not limited thereto. As an example, the light shielding layer LS may be omitted according to the design. As an example, the plurality of high potential power lines VDD, the plurality of data lines DL, the plurality of reference lines RL, and the light shielding layer LS are disposed on different layers on the lower substrate 110 and/or may be formed of different conductive materials.

The plurality of high potential power lines VDD is wiring lines which transmit the high potential power voltage to each of the plurality of sub pixels SP. The plurality of high potential power lines VDD extends between the plurality of sub pixels SP in a column direction and two sub pixels SP which are adjacent to each other in the row direction may share one high potential power line VDD among the plurality of high potential power lines VDD. For example, one high potential power line VDD is disposed at a left side of the red sub pixel SPR to supply a high potential power voltage to the first transistor TR1 of each of the red sub pixel SPR and the white sub pixel SPW. The other high potential power line VDD is disposed at a right side of the green sub pixel SPG to supply a high potential power voltage to the first transistor TR1 of each of the blue sub pixel SPB and the green sub pixel SPG. Embodiments are not limited thereto. The number and/or position of the high potential power line VDD may be variously set. As an example, more than two sub pixels SP in the same row may share one high potential power line VDD. As another example, the high potential power line VDD may be not shared among sub pixels SP in the same row.

The plurality of data lines DL is lines which extend between the plurality of sub pixels SP in a column direction to transmit a data voltage to each of the plurality of sub pixels SP and includes a first data line DL1, a second data line DL2, a third data line DL3, and a fourth data line DL4. The first data line DL1 is disposed between the red sub pixel SPR and the white sub pixel SPW to transmit a data voltage to the second transistor TR2 of the red sub pixel SPR. The second data line DL2 is disposed between the first data line DL1 and the white sub pixel SPW to transmit the data voltage to the second transistor TR2 of the white sub pixel SPW. The third data line DL3 is disposed between the blue sub pixel SPB and the green sub pixel SPG to transmit a data voltage to the second transistor TR2 of the blue sub pixel SPB. The fourth data line DL4 is disposed between the third data line DL3 and the green sub pixel SPG to transmit the data voltage to the second transistor TR2 of the green sub pixel SPG. Embodiments are not limited thereto. As an example, the number and/or position of the data lines DL may be variously set.

The plurality of reference lines RL extends between the plurality of sub pixels SP in the column direction to transmit a reference voltage to each of the plurality of sub pixels SP. The plurality of sub pixels SP which forms one pixel may share one reference line RL. For example, one reference line RL is disposed between the white sub pixel SPW and the blue sub pixel SPB to transmit a reference voltage to a third transistor TR3 of each of the red sub pixel SPR, the white sub pixel SPW, the blue sub pixel SPB, and the green sub pixel SPG, without being limited thereto. The number and/or position of the reference line RL may be variously set.

Referring to FIGS. 4 and 5 together, a light shielding layer LS is disposed on the lower buffer layer 116. The light shielding layer LS is disposed to overlap with the first active layer ACT1 of at least the first transistor TR1 among the plurality of transistors TR1, TR2, and TR3 to block or reduce light incident onto the first active layer ACT1. If light is irradiated onto the first active layer ACT1, a leakage current is generated so that the reliability of the first transistor TR1 which is a driving transistor may be degraded. At this time, if the light shielding layer LS configured by an opaque material is disposed to overlap with the first active layer ACT1, light incident from the lower portion of the lower substrate 110 onto the first active layer ACT1 may be reduced or blocked. As an example, the light shielding layer LS may be configured by an opaque conductive material, such as copper (Cu), aluminum (Al), molybdenum (Mo), nickel (Ni), titanium (Ti), chrome (Cr), or an alloy thereof, without being limited thereto. Accordingly, the reliability of the first transistor TR1 may be improved. However, it is not limited thereto and the light shielding layer LS may be disposed to overlap with the second active layer ACT2 of the second transistor TR2 and the third active layer ACT3 of the third transistor TR3 or may be omitted.

In the meantime, even though in the drawing, it is illustrated that the light single layer LS is a single layer, the light shielding layer LS may be formed as a plurality of layers. For example, the light shielding layer LS may be formed of a plurality of layers. For example, the plurality of layers may be disposed to overlap with each other with at least one of the lower buffer layer 116, the upper buffer layer 111, the gate insulating layer 112, and the passivation layer 113 therebetween.

The upper buffer layer 111 is disposed on the plurality of high potential power lines VDD, the plurality of data lines DL, the plurality of reference lines RL, and the light shielding layer LS. The upper buffer layer 111 may reduce or minimize permeation of moisture or impurities through the lower substrate 110. For example, the upper buffer layer 111 may be configured by a single layer or a double layer or a multiple layer of silicon oxide SiOx or silicon nitride SiNx, but is not limited thereto. Further, the upper buffer layer 111 may be omitted depending on a type of lower substrate 110 or a type of transistor, but is not limited thereto.

In each of the plurality of sub pixels SP, the first transistor TR1, the second transistor TR2, the third transistor TR3, and the storage capacitor SC are disposed on the upper buffer layer 111.

First, the first transistor TR1 includes a first active layer ACT1, a first gate electrode GE1, a first source electrode SE1, and a first drain electrode DE1.

The first active layer ACT1 is disposed on the upper buffer layer 111. The first active layer ACT1 may be formed of a semiconductor material such as an oxide semiconductor, amorphous silicon, and polysilicon, but is not limited thereto. For example, the first active layer ACT1 may be formed by a channel region, a source region, and a drain region and the source region and the drain region may be conductive regions, but are not limited thereto.

The gate insulating layer 112 is disposed on the first active layer ACT1. The gate insulating layer 112 is a layer for electrically insulating the first gate electrode GE1 from the first active layer ACT1 and may be formed of an insulating material. For example, the gate insulating layer 112 may be configured by a single layer or a double layer or a multiple layer of silicon oxide SiOx or silicon nitride SiNx, but is not limited thereto.

The first gate electrode GE1 is disposed on the gate insulating layer 112 to overlap with the first active layer ACT1. The first gate electrode GE1 may be configured by a conductive material such as copper (Cu), aluminum (Al), molybdenum (Mo), nickel (Ni), titanium (Ti), and chrome (Cr), or an alloy thereof, but is not limited thereto.

A first source electrode SE1 and a first drain electrode DE1 which are spaced apart from each other are disposed on the gate insulating layer 112. The first source electrode SE1 and the first drain electrode DE1 may be electrically connected to the first active layer ACT1 through a contact hole formed on the gate insulating layer 112. The first source electrode SE1 and the first drain electrode DE1 may be disposed on the same layer as the first gate electrode GE1 to be formed of the same conductive material, but is not limited thereto. For example, the first source electrode SE1 and the first drain electrode DE1 may be configured by copper (Cu), aluminum (Al), molybdenum (Mo), nickel (Ni), titanium (Ti), chrome (Cr), or an alloy thereof, but is not limited thereto.

The first drain electrode DE1 is electrically connected to the high potential power line VDD. For example, the first drain electrodes DE1 of the red sub pixel SPR and the white sub pixel SPW may be electrically connected to the high potential power line VDD at the left side of the red sub pixel SPR. The first drain electrodes DE1 of the blue sub pixel SPB and the green sub pixel SPG may be electrically connected to the high potential power line VDD at the right side of the green sub pixel SPG.

At this time, an auxiliary high potential power line VDDa may be further disposed to electrically connect the first drain electrode DE1 with the high potential power line VDD. One end of the auxiliary high potential power line VDDa is electrically connected to the high potential power line VDD and the other end may be electrically connected to the first drain electrode DE1 of each of the plurality of sub pixels SP. For example, when the auxiliary high potential power line VDDa is formed of the same material on the same layer as the first drain electrode DE1, one end of the auxiliary high potential power line VDDa is electrically connected to the high potential power line VDD through a contact hole formed in the gate insulating layer 112 and the upper buffer layer 111. The other end of the auxiliary high potential power line VDDa extends to the first drain electrode DE1 to be integrally formed with the first drain electrode DE1. Embodiments are not limited thereto. For example, the auxiliary high potential power line VDDa may also be formed of different material on the same layer as the first drain electrode DE1. For example, when the auxiliary high potential power line VDDa is formed on a different layer from the first drain electrode DE1, one end of the auxiliary high potential power line VDDa may be electrically connected to the first drain electrode DE1 through a contact hole formed in the gate insulating layer 112 and the upper buffer layer 111.

At this time, the first drain electrode DE1 of the red sub pixel SPR and the first drain electrode DE1 of the white sub pixel SPW which are electrically connected to the same high potential power lines VDD may be connected to the same or different auxiliary high potential power line VDDa. The first drain electrode DE1 of the blue sub pixel SPB and the first drain electrode DE1 of the green sub pixel SPG may also be connected to the same or different auxiliary high potential power line VDDa. However, the first drain electrode DE1 and the high potential power line VDD may be electrically connected by another method, but it is not limited thereto.

The first source electrode SE1 may be electrically connected to the light shielding layer LS through a contact hole formed on the gate insulating layer 112 and the upper buffer layer 111. Further, a part of the first active layer ACT1 connected to the first source electrode SE1 may be electrically connected to the light shielding layer LS through a contact hole formed on the upper buffer layer 111. If the light shielding layer LS is floated, a threshold voltage of the first transistor TR1 fluctuates to affect the driving of the display device 100. Accordingly, the light shielding layer LS is electrically connected to the first source electrode SE1 to apply a voltage to the light shielding layer LS and it does not affect the driving of the first transistor TR1. However, in the present specification, even though it has been described that both the first active layer ACT1 and the first source electrode SE1 are in contact with the light shielding layer LS, only any one of the first source electrode SE1 and the first active layer ACT1 may be in direct contact with the light shielding layer LS, but it is not limited thereto. As another example, neither of the first source electrode SE1 and the first active layer ACT1 may be in direct contact with the light shielding layer LS.

In the meantime, even though in FIG. 5, it is illustrated that the gate insulating layer 112 is formed on the entire lower substrate 110, the gate insulating layer 112 may be patterned to overlap with only the first gate electrode GE1, the first source electrode SE1, and the first drain electrode DE1, but is not limited thereto.

The second transistor TR2 includes a second active layer ACT2, a second gate electrode GE2, a second source electrode SE2, and a second drain electrode DE2.

The second active layer ACT2 is disposed on the upper buffer layer 111. The second active layer ACT2 may be formed of a semiconductor material such as an oxide semiconductor, amorphous silicon, and polysilicon, but is not limited thereto. For example, when the second active layer ACT2 is formed of an oxide semiconductor, the second active layer ACT2 may be formed by a channel region, a source region, and a drain region and the source region and the drain region may be conductive regions, but are not limited thereto.

The second source electrode SE2 may be disposed on the upper buffer layer 111. The second source electrode SE2 may be integrally formed with the second active layer ACT2 to be electrically connected to each other. For example, the semiconductor material is formed on the upper buffer layer 111 and a part of the semiconductor material is conducted to form the second source electrode SE2. Therefore, a part of the semiconductor material which is not conducted may become a second active layer ACT2 and a conducted part serves as a second source electrode SE2. However, the second active layer ACT2 and the second source electrode SE2 may also be separately formed on the same or different layer, but are not limited thereto.

The second source electrode SE2 is electrically connected to the first gate electrode GE1 of the first transistor TR1. The first gate electrode GE1 may be electrically connected to the second source electrode SE2 through a contact hole formed on the gate insulating layer 112. Accordingly, the first transistor TR1 may be turned on or turned off by a signal from the second transistor TR2.

The gate insulating layer 112 is disposed on the second active layer ACT2 and the second source electrode SE2 and the second drain electrode DE2 and the second gate electrode GE2 are disposed on the gate insulating layer 112.

The second gate electrode GE2 is disposed on the gate insulating layer 112 to overlap with the second active layer ACT2. The second gate electrode GE2 may be electrically connected to the gate line GL and the second transistor TR2 may be turned on or turned off based on the gate voltage transmitted to the second gate electrode GE2. The second gate electrode GE2 may be configured by a conductive material such as copper (Cu), aluminum (Al), molybdenum (Mo), nickel (Ni), titanium (Ti), and chrome (Cr), or an alloy thereof, but is not limited thereto.

In the meantime, the second gate electrode GE2 may extend from the gate line GL. That is, the second gate electrode GE2 may be integrally formed with the gate line GL and the second gate electrode GE2 and the gate line GL may be formed of the same conductive material. For example, the gate line GL may be configured by copper (Cu), aluminum (Al), molybdenum (Mo), nickel (Ni), titanium (Ti), chrome (Cr), or an alloy thereof, but is not limited thereto. Embodiments are not limited thereto. As an example, the second gate electrode GE2 and the gate line GL may also be separately formed of the same or different materials.

The gate line GL is a wiring line which transmits the gate voltage to each of the plurality of sub pixels SP and intersects the circuit area of the plurality of sub pixels SP to extend in the row direction. The gate line GL extends in the row direction to intersect the plurality of high potential power lines VDD, the plurality of data lines DL, and the plurality of reference lines RL extending in the column direction.

The second drain electrode DE2 is disposed on the gate insulating layer 112. The second drain electrode DE2 is electrically connected to the second active layer ACT2 through a contact hole formed in the gate insulating layer 112 and is electrically connected to one of the plurality of data lines DL through a contact hole formed in the gate insulating layer 112 and the upper buffer layer 111, simultaneously. For example, the second drain electrode DE2 of the red sub pixel SPR is electrically connected to the first data line DL1 and the second drain electrode DE2 of the white sub pixel SPW may be electrically connected to the second data line DL2. For example, the second drain electrode DE2 of the blue sub pixel SPB is electrically connected to the third data line DL3 and the second drain electrode DE2 of the green sub pixel SPG may be electrically connected to the fourth data line DL4. The second drain electrode DE2 may be configured by a conductive material, such as copper (Cu), aluminum (Al), molybdenum (Mo), nickel (Ni), titanium (Ti), and chrome (Cr), or an alloy thereof, but is not limited thereto.

The third transistor TR3 includes a third active layer ACT3, a third gate electrode GE3, a third source electrode SE3, and a third drain electrode DE3.

The third active layer ACT3 is disposed on the upper buffer layer 111. The third active layer ACT3 may be formed of a semiconductor material, such as an oxide semiconductor, amorphous silicon, and polysilicon, but is not limited thereto. For example, when the third active layer ACT3 is formed of an oxide semiconductor, the third active layer ACT3 is formed by a channel region, a source region, and a drain region and the source region and the drain region may be conductive regions, but are not limited thereto.

The gate insulating layer 112 is disposed on the third active layer ACT3 and the third gate electrode GE3, the third source electrode SE3, and the third drain electrode DE3 are disposed on the gate insulating layer 112.

The third gate electrode GE3 is disposed on the gate insulating layer 112 to overlap with the third active layer ACT3. The third gate electrode GE3 may be electrically connected to the sensing line SL and the third transistor TR3 may be turned on or turned off based on the sensing voltage transmitted to the third transistor TR3. The third gate electrode GE3 may be configured by a conductive material such as copper (Cu), aluminum (Al), molybdenum (Mo), nickel (Ni), titanium (Ti), and chrome (Cr), or an alloy thereof, but is not limited thereto.

In the meantime, the third gate electrode GE3 may extend from the sensing line SL. That is, the third gate electrode GE3 may be integrally formed with the sensing line SL and the third gate electrode GE3 and the sensing line SL may be formed of the same conductive material. For example, the sensing line SL may be configured by copper (Cu), aluminum (Al), molybdenum (Mo), nickel (Ni), titanium (Ti), chrome (Cr), or an alloy thereof, but is not limited thereto. Embodiments are not limited thereto. As an example, the third gate electrode GE3 and the sensing line SL may also be separately formed of the same or different materials.

The sensing line SL transmits a sensing voltage to each of the plurality of sub pixels SP and extends between the plurality of sub pixels SP in a row direction. For example, the sensing line SL extends at a boundary between the plurality of sub pixels SP in the row direction to intersect the plurality of high potential power lines VDD, the plurality of data lines DL, and the plurality of reference lines RL extending in the column direction.

The third source electrode SE3 may be electrically connected to the third active layer ACT3 through a contact hole formed on the gate insulating layer 112. The third source electrode SE3 may be configured by a conductive material, such as copper (Cu), aluminum (Al), molybdenum (Mo), nickel (Ni), titanium (Ti), and chrome (Cr), or an alloy thereof, but is not limited thereto.

In the meantime, a part of the third active layer ACT3 which is in contact with the third source electrode SE3 may be electrically connected to the light shielding layer LS through a contact hole formed in the upper buffer layer 111, without being limited thereto. That is, the third source electrode SE3 may be electrically connected to the light shielding layer LS with the third active layer ACT3 therebetween. Therefore, the third source electrode SE3 and the first source electrode SE1 may be electrically connected to each other by means of the light shielding layer LS. Embodiments are not limited thereto. As an example, the third source electrode SE3 and the first source electrode SE1 may be electrically connected to each other by means of another electrode or wiring other than the light shielding layer LS. As an example, neither of or only one of the third source electrode SE3 and the first source electrode SE1 may be electrically connected to the light shielding layer LS.

The third drain electrode DE3 may be electrically connected to the third active layer ACT3 through a contact hole formed on the gate insulating layer 112. The third drain electrode DE3 may be configured by a conductive material such as copper (Cu), aluminum (Al), molybdenum (Mo), nickel (Ni), titanium (Ti), and chrome (Cr), or an alloy thereof, but is not limited thereto.

The third drain electrode DE3 may be electrically connected to the reference line RL. For example, the third drain electrodes DE3 of the red sub pixel SPR, the white sub pixel SPW, the blue sub pixel SPB, and the green sub pixel SPG may be electrically connected to the same reference line RL. That is, the plurality of sub pixels SP which forms one pixel may share one reference line RL. Embodiments are not limited thereto. As an example, one reference line RL may be shared by only some of the plurality of sub pixels SP which forms one pixel, may be shared by the plurality of sub pixels SP which forms more than one pixel in the same row, or may not be shared by the plurality of sub pixels SP in the same row.

At this time, an auxiliary reference line RLa may be disposed to transmit the reference line RL extending in the column direction to the plurality of sub pixels SP which is disposed in parallel along the row direction. The auxiliary reference line RLa extends in the row direction to electrically connect the reference line RL and the third drain electrode DE3 of each of the plurality of sub pixels SP. One end of the auxiliary reference line RLa may be electrically connected to the reference line RL through a contact hole formed in the upper buffer layer 111 and the gate insulating layer 112. Further, the other end of the auxiliary reference line RLa may be electrically connected to the third drain electrode DE3 of each of the plurality of sub pixels SP. In this case, the auxiliary reference line RLa may be integrally formed with the third drain electrode DE3 of each of the plurality of sub pixels SP and a reference voltage from the reference line RL may be transmitted to the third drain electrode DE3 by means of the auxiliary reference line RLa. However, the auxiliary reference line RLa may be separately formed from the third drain electrode DE3, but is not limited thereto.

The storage capacitor SC is disposed in the circuit area of the plurality of sub pixels SP. The storage capacitor SC may store a voltage between the first gate electrode GE1 and the first source electrode SE1 of the first transistor TR1 to allow the light emitting diode OLED to continuously maintain a constant state for one frame. The storage capacitor SC includes a first capacitor electrode SC1 and a second capacitor electrode SC2.

In each of the plurality of sub pixels SP, the first capacitor electrode SC1 is disposed between the lower buffer layer 116 and the upper buffer layer 111. The first capacitor electrode SC1 may be disposed to be the closest to the lower substrate 110 among the conductive components disposed on the lower substrate 110. The first capacitor electrode SC1 is integrally formed with the light shielding layer LS and may be electrically connected to the first source electrode SE1 by means of the light shielding layer LS. Embodiments are not limited thereto. As an example, the first capacitor electrode SC1 may be separately formed with the light shielding layer LS, and may be electrically connected to the first source electrode SE1 by means of another electrode or wiring other than the light shielding layer LS.

The upper buffer layer 111 is disposed on the first capacitor electrode SC1 and the second capacitor electrode SC2 is disposed on the upper buffer layer 111. The second capacitor electrode SC2 may be disposed to overlap with the first capacitor electrode SC1. The second capacitor electrode SC2 may be electrically connected to the second source electrode SE2 and the first gate electrode GE1. The second capacitor electrode SC2 may be integrally formed with the second source electrode SE2 to be electrically connected to the second source electrode SE2 and the first gate electrode GE1. For example, the semiconductor material is formed on the upper buffer layer 111 and a part of the semiconductor material is conducted to form the second source electrode SE2 and the second capacitor electrode SC2. Accordingly, a part of the semiconductor material which is not conducted functions as a second active layer ACT2 and the conducted part may function as a second source electrode SE2 and the second capacitor electrode SC2. Further, as described above, the first gate electrode GE1 is electrically connected to the second source electrode SE2 through the contact hole formed in the gate insulating layer 112. Accordingly, the second capacitor electrode SC2 is integrally formed with the second source electrode SE2 to be electrically connected to the second source electrode SE2 and the first gate electrode GE1. Embodiments are not limited thereto. As an example, the second capacitor electrode SC2 may be separately formed with the second source electrode SE2.

In summary, the first capacitor electrode SC1 of the storage capacitor SC is integrally formed with the light shielding layer LS to be electrically connected to the light shielding layer LS, the first source electrode SE1, and the third source electrode SE3. Further, the second capacitor electrode SC2 is integrally formed with the second source electrode SE2 and the second active layer ACT2 to be electrically connected to the second source electrode SE2 and the first gate electrode GE1. Accordingly, the first capacitor electrode SC1 and the second capacitor electrode SC2 which overlap with the upper buffer layer 111 therebetween constantly maintain the voltage of the first gate electrode GE1 and the first source electrode SE1 of the first transistor TR1 to maintain the constant state of the light emitting diode OLED.

The passivation layer 113 is disposed on the first transistor TR1, the second transistor TR2, the third transistor TR3, and the storage capacitor SC. The passivation layer 113 is an insulating layer for protecting components below the passivation layer 113. For example, the passivation layer 113 may be configured by a single layer or a double layer or a multiple of silicon oxide SiOx or silicon nitride SiNx, but is not limited thereto. Further, the passivation layer 113 may be omitted depending on the exemplary aspect.

A plurality of color filters CF is disposed in the emission area of each of the plurality of sub pixels SP on the passivation layer 113. As described above, the display device 100 according to the exemplary aspect of the present disclosure is a bottom emission type in which light emitted from the light emitting diode OLED is directed to the lower portion of the light emitting diode OLED and the lower substrate 110. Therefore, the plurality of color filters CF may be disposed below the light emitting diode OLED. Light emitted from the light emitting diode OLED passes through the plurality of color filters CF and may be implemented as various colors of light.

The plurality of color filters CF may include a red color filter CFR, a blue color filter CFB, and a green color filter CFG. The red color filter CFR may be disposed in an emission area of a red sub pixel SPR of the plurality of sub pixels SP, the blue color filter CFB may be disposed in an emission area of the blue sub pixel SPB, and the green color filter CFG may be disposed in an emission area of the green sub pixel SPG. As an example, the color filters CF may be omitted according to the design of the sub pixels.

The planarization layer 114 is disposed on the passivation layer 113 and the plurality of color filters CF. The planarization layer 114 is an insulating layer which planarizes an upper portion of the lower substrate 110 on which the first transistor TR1, the second transistor TR2, the third transistor TR3, the storage capacitor SC, the plurality of high potential power lines VDD, the plurality of data lines DL, the plurality of reference lines RL, the plurality of gate lines GL, and the plurality of sensing lines SL are disposed. The planarization layer 114 may be formed of an organic material, and for example, may be configured by a single layer or a double layer or a multiple layer of polyimide or photo acryl, but is not limited thereto.

The light emitting diode OLED is disposed in an emission area of each of the plurality of sub pixels SP. The light emitting diode OLED is disposed on the planarization layer 114 in each of the plurality of sub pixels SP. The light emitting diode OLED includes an anode AN, an emission layer EL, and a cathode CA.

The anode AN is disposed on the planarization layer 114 in the emission area. The anode AN supplies holes to the emission layer EL so that the anode may be formed of a conductive material having a high work function. It may also be referred to as an anode (AN). For example, the anode AN may be formed of a transparent conductive material such as indium tin oxide (ITO) and indium zinc oxide (IZO), but is not limited thereto.

In the meantime, the anode AN may extend toward the circuit area. A part of the anode AN may extend toward the first source electrode SE1 of the circuit area from the emission area and may be electrically connected to the first source electrode SE1 through a contact hole formed in the planarization layer 114 and the passivation layer 113. Accordingly, the anode AN of the light emitting diode OLED extends to the circuit area to be electrically connected to the first source electrode SE1 of the first transistor TR1 and the second capacitor electrode SC2 of the storage capacitor SC.

In the emission area and the circuit area, the emission layer EL is disposed on the anode AN. The emission layer EL may be formed as one layer over the plurality of sub pixels SP. That is, the emission layers EL of the plurality of sub pixels SP are connected to each other to be integrally formed. Embodiments are not limited thereto. As an example, the emission layer EL may be separately formed in each of the plurality of sub pixels SP, or may be integrally formed in only some of the plurality of sub pixels SP. The emission layer EL may be configured by one emission layer or may have a structure in which a plurality of emission layers which emits different color light is laminated. The emission layer EL may further include an organic layer, such as a hole injection layer, a hole transport layer, an electron transport layer, and an electron injection layer, without being limited thereto. As an example, at least one of the hole injection layers, the hole transport layer, the electron transport layer, and the electron injection layer may be omitted.

The cathode CA is disposed on the emission layer EL in the emission area and the circuit area. The cathode CA supplies electrons to the emission layer EL so that the cathode may be formed of a conductive material having a low work function. The cathode CA may be formed as one layer over the plurality of sub pixels SP. That is, the cathodes CA of the plurality of sub pixels SP are connected to be integrally formed. For example, the cathode CA may be formed of a transparent conductive material such as indium tin oxide (ITO), indium zinc oxide (IZO) and ytterbium (Yb) alloy and may further include a metal doping layer, but is not limited thereto. In the meantime, even though it is not illustrated in FIGS. 4 and 5, the cathode CA of the light emitting diode OLED is electrically connected to the low potential power line VSS to be supplied with a low potential power voltage.

The bank 115 is disposed between the anode AN and the emission layer EL. The bank 115 is disposed to overlap with the active area AA and cover the edge of the anode AN. The bank 115 is disposed at the boundary between the sub pixels SP which are adjacent to each other to reduce the color mixture of light emitted from the light emitting diode OLED of each of the plurality of sub pixels SP. As an example, the bank 115 may be formed of an opaque material, but it is not limited thereto. The bank 115 may be formed of an insulating material such as, polyimide, acryl, and benzocyclobutene (BCB)-based resin, but it is not limited thereto.

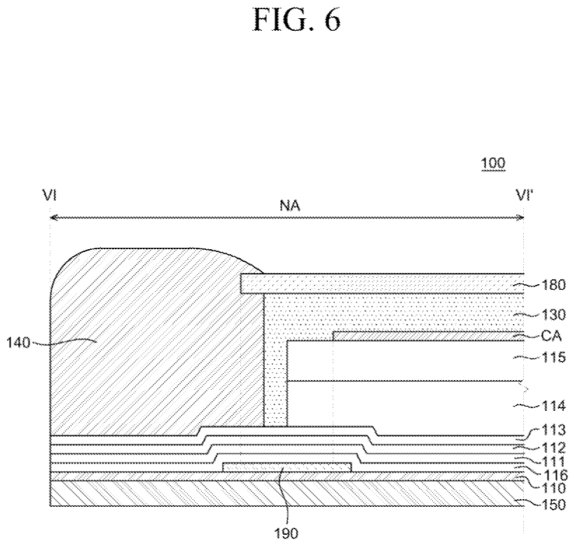

FIG. 6 is a cross-sectional view taken along line VI-VI′ of FIG. 1 according to an exemplary embodiment of the present disclosure. Even though FIG. 6 is a cross-sectional view of a left non-active area of a display device illustrated in FIG. 1, the same cross-section may be applied to upper, right, and lower non-active areas of the display device 100.

Referring to FIGS. 1 and 6, a rigid unit 190 is disposed in the non-active area NA which encloses the active area AA on the lower substrate 110. The rigid unit 190 is disposed along the non-active area NA to be disposed in all the upper, lower, left, and right non-active areas NA of the display device 100 to enclose the active area AA. For example, the rigid unit 190 may be disposed in the non-active area NA to have a rectangular ring shape which encloses the active area AA, but is not limited thereto.

The rigid unit 190 is disposed to enclose the active area AA in the non-active area NA with a predetermined width. For example, the rigid unit 190 may be disposed in a part of the non-active area NA to enclose the active area AA with a width smaller than a width of the non-active area NA. Embodiments are not limited thereto. As an example, the rigid unit 190 may be disposed to have different widths and/or different distances from the active area depending on the location in the non-active area NA, without being limited thereto.

The rigid unit 190 is disposed on the lower substrate 110. Referring to FIG. 6, the rigid unit 190 may be disposed to be in contact with the lower substrate 110. In the non-active area NA, conductive components such as a gate driver, other circuits, and wiring lines are disposed. The conductive components may be disposed between a lower buffer layer 116 and an upper buffer layer 111, between the upper buffer layer 111 and the gate insulating layer 112, or between the gate insulating layer 112 and the passivation layer 113. Therefore, to suppress the rigid unit 190 from being in contact with the conductive components, the rigid unit 190 may be disposed to be in contact with a top surface of the lower substrate 110. However, it is not limited thereto and an additional insulating layer may be disposed between the lower substrate 110 and the rigid unit 190 so that the rigid unit 190 may be disposed so as not to be in contact with the top surface of the lower substrate 110. Further, in a space in which electric contact with the above-described conductive components is not performed, the rigid unit 190 may be disposed in any one between the lower buffer layer 116 and the upper buffer layer 111, between the upper buffer layer 111 and the gate insulating layer 112, or between the gate insulating layer 112 and a passivation layer 113.

The rigid unit 190 is disposed to overlap with an end of the cathode CA and an end of the encapsulation substrate 180. An inner side of the rigid unit 190 is disposed to overlap with an end of the cathode CA and an outer side of the rigid unit 190 is disposed to overlap with an end of the encapsulation substrate 180. Specifically, an inner side of the rigid unit 190 is disposed inside from a location in which the rigid unit 190 overlaps with an end of the cathode CA and an outer side thereof is disposed outside from a location in which the rigid unit 190 and the end of the encapsulation substrate 180 overlap with each other.

The rigid unit 190 is formed of a material having rigidity to ensure the rigidity in the outer peripheral area of the display device 100. For example, the rigid unit 190 may be formed of ceramic or a metal material. When the rigid unit 190 is formed of ceramic, the ceramic is not a conductive material so that a parasitic capacitance with various conductive components which may be disposed above the rigid unit 190 may be reduced. Further, when the rigid unit 190 is formed of a metal material, the rigid unit 190 blocks laser used for the LLO process to suppress the damage of other configurations above the rigid unit 190 and provide a higher rigidity than the ceramic.

In the display device 100 according to the exemplary aspect of the present disclosure, the lower substrate 110 may be formed of any one of a transparent conducting oxide and an oxide semiconductor to reduce a thickness of the display device 100. In the related art, the plastic substrate has been mainly used as the substrate of the display device. However, the plastic substrate is formed by coating and curing a substrate material at a high temperature so that there are problems in that it takes a long time and it is difficult to form the thin thickness to be equal to or lower than a predetermined level. In contrast, the transparent conducting oxide and the oxide semiconductor may be formed to have a very thin thickness by the deposition process such as sputtering. Therefore, in the display device 100 according to the exemplary aspect of the present disclosure, the lower substrate 110 which supports various components of the display device 100 is configured by a transparent conducting oxide layer or the oxide semiconductor layer to reduce a thickness of the display device 100 and implement a slim design.

Further, in the display device 100 according to the exemplary aspect of the present disclosure, the lower substrate 110 is formed of a transparent conducting oxide or an oxide semiconductor to improve the flexibility of the display device 100 and reduce the stress generated when the display device 100 is deformed. Specifically, when the lower substrate 110 is configured by the transparent conducting oxide layer or the oxide semiconductor, the lower substrate 110 may be formed as a very thin film. In this case, the lower substrate 110 is also referred to as a first transparent thin film layer. Accordingly, the display device 110 including the lower substrate 110 may have a high flexibility and the display device 100 may be easily bent or rolled. Therefore, in the display device 100 according to the exemplary aspect of the present disclosure, the lower substrate 110 is formed by any one of the transparent conducting oxide layer and the oxide semiconductor layer to improve the flexibility of the display device 100. Accordingly, the stress generated when the display device 100 is deformed is also relieved so that the crack generated in the display device 100 may be reduced or minimized.

Further, in the display device 100 according to the exemplary aspect of the present disclosure, the lower substrate 110 is formed of any one of a transparent conducting oxide layer and an oxide semiconductor layer to reduce the possibility of generating the static electricity in the lower substrate 110. If the lower substrate 110 is formed of plastic so that the static electricity is generated, various wiring lines and driving elements on the lower substrate 110 are damaged or the driving is affected due to the static electricity to degrade the display quality. Instead, when the lower substrate 110 is formed of the transparent conducting oxide layer or the oxide semiconductor layer, the static electricity generated in the lower substrate 110 is reduced or minimized and a configuration for blocking and discharging the static electricity may be simplified. Accordingly, in the display device 100 according to the exemplary aspect of the present disclosure, the lower substrate 110 is formed of any one of the transparent conducting oxide layer or the oxide semiconductor layer having a low possibility of generating the static electricity. By doing this, the damage or the display quality degradation due to the static electricity may be reduced or minimized.

Further, in the display device 100 according to the exemplary aspect of the present disclosure, the lower substrate 110 is formed of one of the transparent conducting oxide and the oxide semiconductor to reduced or minimize the permeation of the moisture or oxygen of the outside into the display device 100 by means of the lower substrate 110. When the lower substrate 110 is formed of the transparent conducting oxide layer or the oxide semiconductor, the lower substrate 110 is formed in the vacuum environment so that the foreign material generation possibility is significantly low. Further, even though the foreign material is generated, the size of the foreign material is very small so that the permeation of the moisture and oxygen into the display device 100 may be reduced or minimized. Accordingly, in the display device 100 according to the exemplary aspect of the present disclosure, the lower substrate 110 is formed of a transparent conducting oxide or the oxide semiconductor having a low possibility of generating the foreign materials and an excellent moisture permeation performance. By doing this, the reliability of the light emitting diode OLED including an organic layer and the display device 100 may be improved.

Further, in the display device 100 according to the exemplary aspect of the present disclosure, the lower substrate 110 is formed of any one of a transparent conducting oxide and an oxide semiconductor to attach a barrier film which is thin and cheap below the lower substrate 110. When the lower substrate 110 is formed of a material having a low moisture permeation performance, for example, plastic, the moisture permeability may be supplemented by attaching a high performance barrier film. However, in the display device 100 according to the exemplary aspect of the present disclosure, the lower substrate 110 is formed of a transparent conducting oxide or an oxide semiconductor having an excellent moisture permeation performance so that a thin and cheap barrier film may be attached below the lower substrate 110 or may be omitted. Accordingly, in the display device 100 according to the exemplary aspect of the present disclosure, the lower substrate 110 is configured by any one of the transparent conducting oxide or the oxide semiconductor having an excellent moisture permeation performance to reduce the manufacturing cost of the display device.

Further, in the display device 100 according to the exemplary aspect of the present disclosure, the lower substrate 110 is formed of any one of a transparent conducting oxide and an oxide semiconductor to perform a laser lift off (LLO) process. When the display device 100 is manufactured, a temporary substrate in which a sacrificial layer is formed is attached below the lower substrate 110 and then a pixel unit 120 is formed on the lower substrate 110. The sacrificial layer may use a hydrogenated amorphous silicon or an amorphous silicon which is hydrogenated and doped with impurities. After completing the manufacturing of the display device 100, when a laser is irradiated from the lower portion of the temporary substrate, the hydrogen of the sacrificial layer is dehydrogenated and the sacrificial layer and the temporary substrate may be separated from the lower substrate 110. At this time, the transparent conducting oxide and the oxide semiconductor are materials which may perform the LLO process with the sacrificial layer and the temporary substrate. Therefore, even though the lower substrate 110 is formed of any one of the transparent conducting oxide or the oxide semiconductor, the lower substrate 110 may be easily separated from the temporary substrate. Accordingly, in the display device 100 according to the exemplary aspect of the present disclosure, the lower substrate 110 is configured by any one of the transparent conducting oxide layer or the oxide semiconductor which may perform the LLO process. Therefore, the display device 100 may be easily manufactured with the existing process and equipment.

In the meantime, when any one of transparent conducting oxide and oxide semiconductor is used as a lower substrate, a thickness of the lower substrate is reduced as compared with a lower substrate which is configured by a plastic substrate. Therefore, after removing a temporary substrate during the above-described LLO process, creases or cracks may be generated in the outer peripheral area of the display device. Specifically, creases or cracks may be generated in the outer peripheral area at the outside of the area in which the cathode is disposed. Further, during a bonding process of a polarizer which is performed after removing the temporary substrate, the creases generated in the outer peripheral area of the display device may cause the crack of the display device or deepen the already generated crack. As described above, when the crack is generated in the outer peripheral area of the display device, the wiring line or circuits are disconnected to cause a driving failure of the display device or cause cracks in various inorganic insulating layers, to degrade the reliability.

Therefore, in the display device 100 according to the exemplary aspect of the present disclosure, the rigid unit 190 is disposed in the outer peripheral area to improve the rigidity of the outer peripheral area. Specifically, the rigid unit 190 is disposed to overlap with an end of the upper substrate 180 in which the most creases are generated after the LLO process and creases or cracks are generated by being dented by a relatively strong upper substrate 180, which, for example, may be relatively strong, without being limited thereto. Further, the rigid unit 190 may be disposed in the outer peripheral area with respect to an area in which the cathode CA in which creases are not generated is disposed and overlap with an end of the cathode CA. Therefore, in the display device 100 according to the exemplary aspect of the present disclosure, the rigidity of the outer peripheral area is improved by means of the rigid unit 190 and the creases or cracks generated in the outer peripheral area of the display device 100 after the LLO process may be reduced or minimized. Therefore, the reliability of the display device 100 may be improved.

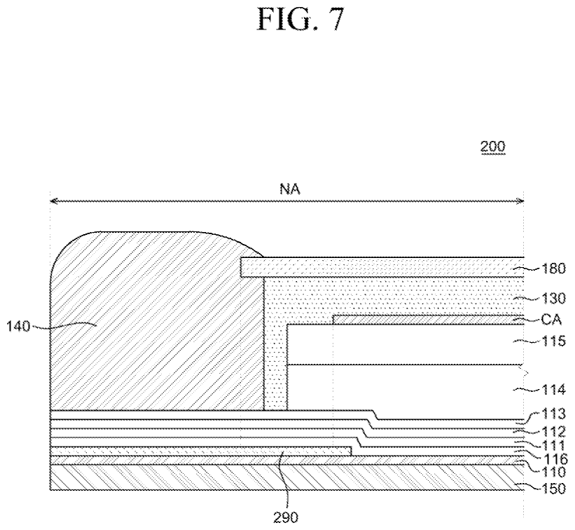

FIG. 7 is a cross-sectional view of a display device according to another exemplary aspect of the present disclosure. The other configuration of a display device 200 of FIG. 7 excluding a rigid unit 290 is substantially the same as the display device 100 of FIGS. 1 to 6, so that a redundant description will be omitted or briefly given.

Referring to FIG. 7, a rigid unit 290 is disposed in the non-active area NA which encloses the active area AA on the lower substrate 110. The rigid unit 290 is disposed along the non-active area NA to be disposed in all the upper, lower, left, and right non-active areas NA of the display device 200 to enclose the active area AA. For example, the rigid unit 290 may be disposed in the non-active area NA to have a square shape which encloses the active area AA, but is not limited thereto. As an example, the rigid unit 290 may be disposed in the non-active area NA to have a shape corresponding to the shape of the active area AA or the shape of the display device 200, which for example could be a circular shape, an oval shape, a quadrangle shape, a polygon shape, etc.

The rigid unit 290 is disposed to enclose the active area AA in the non-active area NA with a predetermined width. For example, the rigid unit 290 may be disposed in a part of the non-active area NA to enclose the active area AA with a width smaller than a width of the non-active area NA.

The rigid unit 290 is disposed to overlap with an end of the cathode CA and an end of the encapsulation substrate 180. An inner side of the rigid unit 290 is disposed inside from the location in which the rigid unit 290 and the end of the cathode CA overlap with and an outer side of the rigid unit 290 may be disposed to the end of the lower substrate 110. Therefore, in the entire area in which the cathode CA is no disposed, the rigid unit 290 may be disposed.

In the display device 200 according to another exemplary aspect of the present disclosure, the rigid unit 290 is disposed in the outer peripheral area to improve the rigidity of the outer peripheral area. Specifically, the rigid unit 290 is disposed to overlap with an end of the upper substrate 180 in which the most creases are generated after the LLO process and creases or cracks are generated by being dented by a relatively strong upper substrate 180. Further, the rigid unit 290 is disposed in the entire outer peripheral area with respect to an area in which the cathode CA in which creases are not generated is disposed to provide the rigidity to the entire outer peripheral area of the display device 200. Therefore, in the display device 200 according to another exemplary aspect of the present disclosure, the rigidity of the outer peripheral area is improved by means of the rigid unit 290 and the creases or cracks generated in the outer peripheral area of the display device 200 after the LLO process may be reduced or minimized. Therefore, the reliability of the display device 200 may be improved.

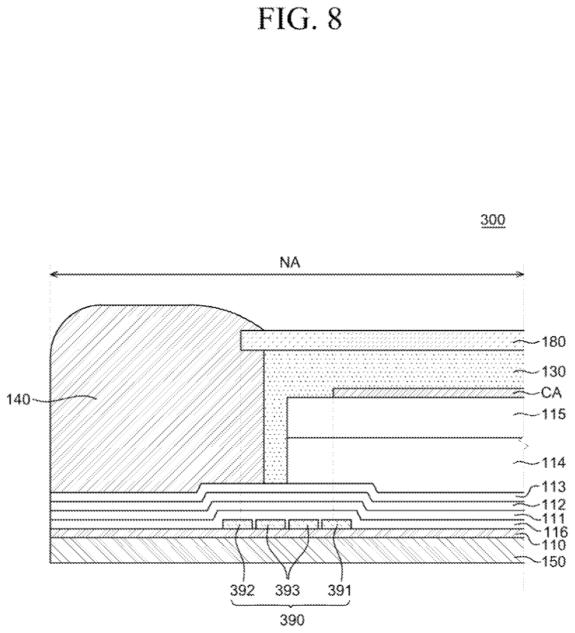

FIG. 8 is a cross-sectional view of a display device according to still another exemplary aspect of the present disclosure. The other configuration of a display device 300 of FIG. 8 excluding a rigid unit 390 is substantially the same as the display device 100 of FIGS. 1 to 6, so that a redundant description will be omitted or briefly given.

Referring to FIG. 8, the rigid unit 390 includes a plurality of rigid patterns 391, 392, and 393 which is spaced apart from each other. For example, the rigid unit 390 may include four rigid patterns 391, 392, and 393, but is not limited thereto. As an example, the rigid unit 390 may include two or three or more than four rigid patterns.

Further, even though in FIG. 8, it is illustrated that the plurality of rigid patterns 391, 392, and 393 is spaced apart from each other with a predetermined interval and has the same width, it is not limited thereto. As an example, the plurality of rigid patterns 391, 392, and 393 may be spaced apart from each other with a varied interval and has varied widths.

Each of the plurality of rigid patterns 391, 392, and 393 of the rigid unit 390 may have a closed curve shape. Therefore, the plurality of rigid patterns 391, 392, and 393 is disposed in the non-active area NA which encloses the active area AA on the lower substrate 110. The plurality of rigid patterns 391, 392, and 393 is disposed along the non-active area NA to be disposed in all the upper, lower, left, and right non-active areas NA of the display device 300 to enclose the active area AA. For example, the plurality of rigid patterns 391, 392, and 393 may be disposed in the non-active area NA to have a rectangular ring shape which encloses the active area AA, but is not limited thereto. As an example, at least some of the plurality of rigid patterns 391, 392, and 393 may be disposed along the non-active area NA to be disposed in all the upper, lower, left, and right non-active areas NA of the display device 300.

The rigid unit 390 includes a first rigid pattern 391, a second rigid pattern 392, and a third rigid pattern 393. Among the plurality of rigid patterns 391, 392, and 393, the first rigid pattern 391 overlaps with an end of the cathode CA. Among the plurality of rigid patterns 391, 392, and 393, the second rigid pattern 392 overlaps with an end of the encapsulation substrate 180. Specifically, the first rigid pattern 391 which is disposed in an innermost side closest to the active area AA, among the plurality of rigid patterns 391, 392, and 393, is disposed to overlap with the end of the cathode CA. The second rigid pattern 392 which is disposed in an outermost side closest to the end of the lower substrate 110, among the plurality of rigid patterns 391, 392, and 393, is disposed to overlap with the end of the encapsulation substrate 180. The inner side of the first rigid pattern 391 is disposed to be closer to the active area AA than the end of the cathode CA and the outer side of the first rigid pattern 391 is disposed to be farther from the active area AA than the end of the cathode CA. The inner side of the second rigid pattern 392 is disposed to be closer to the active area AA than the end of the encapsulation substrate 180 and the outer side of the second rigid pattern 392 is disposed to be farther from the active area AA than the end of the encapsulation substrate 180. That is, the rigid unit 390 is disposed in an area overlapping with the end of the cathode CA and the end of the encapsulation substrate 180. Embodiments are not limited thereto. As an example, the rigid unit 390 may further include a rigid pattern inner than the first rigid pattern 391 and/or a rigid pattern outer than the second rigid pattern 392.

The third rigid pattern 393 is disposed between the first rigid pattern 391 and the second rigid pattern 392. However, the third rigid pattern 393 may be omitted depending on the design. Further, the number of third rigid patterns 393 may also vary depending on the design.

In the display device 300 according to still another exemplary aspect of the present disclosure, the rigid unit 390 including the plurality of rigid patterns 391, 392, and 393 is disposed in the outer peripheral area to improve the rigidity of the outer peripheral area. Specifically, the plurality of rigid patterns 391, 392, and 393 of the rigid unit 390 is disposed to overlap with an end of the upper substrate 180 in which the most creases are generated after the LLO process and creases or cracks are generated by being dented by a relatively strong upper substrate 180. Further, the rigid unit 390 may be disposed in the outer peripheral area with respect to an area in which the cathode CA in which creases are not generated is disposed and overlap with an end of the cathode CA. Therefore, in the display device 300 according to still another exemplary aspect of the present disclosure, the rigidity of the outer peripheral area is improved by means of the plurality of rigid patterns 391, 392, and 393 of the rigid unit 390 and the creases or cracks generated in the outer peripheral area of the display device 300 after the LLO process may be reduced or minimized. Therefore, the reliability of the display device 300 may be improved.

In the display device 300 according to still another exemplary aspect of the present disclosure, the rigid unit 390 includes a plurality of rigid patterns 391, 392, and 393 which is spaced apart from each other to reduced or minimize a parasitic capacitance which may be generated by the rigid unit 390 while ensuring the rigidity of the outer peripheral area. As described above, in the non-active area, conductive components, such as a gate driver, other circuits, and wiring lines are disposed. At this time, when the rigid unit 390 is formed of a metal material, a parasitic capacitance between the above-described conductive components and the rigid unit 390 may be generated. The parasitic capacitance may be increased as an overlapping area of the conductive component and the rigid unit 390 is increased. Therefore, in the display device 300 according to still another exemplary aspect of the present disclosure, the rigid unit 390 includes a plurality of rigid patterns 391, 392, and 393 which is spaced apart from each other to reduced or minimize an area in which the rigid unit 390 and the conductive components overlap with each other. Accordingly, the rigidity of the outer peripheral area is improved and the parasitic capacitance generated by the rigid unit 390 is reduced or minimized to improve the reliability of the display device 300.

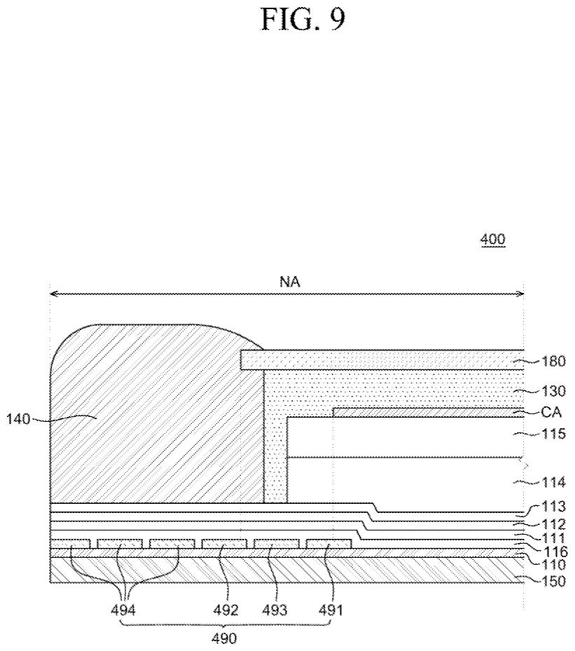

FIG. 9 is a cross-sectional view of a display device according to still another exemplary aspect of the present disclosure. The other configuration of a display device 400 of FIG. 9 excluding a rigid unit 490 is substantially the same as the display device 100 of FIGS. 1 to 6, so that a redundant description will be omitted or briefly given.

Referring to FIG. 9, the rigid unit 490 includes a plurality of rigid patterns 491, 492, 493, and 494 which is spaced apart from each other. For example, the rigid unit 490 may include six rigid patterns 491, 492, 493, and 494, but is not limited thereto.

Further, even though in FIG. 9, it is illustrated that the plurality of rigid patterns 491, 492, 493, and 494 is spaced apart from each other with a predetermined interval and has the same width, it is not limited thereto. As an example, the plurality of rigid patterns 91, 492, 493, and 494 may be spaced apart from each other with a varied interval and has varied widths.

Each of the plurality of rigid patterns 491, 492, 493, and 494 of the rigid unit 490 may have a closed curve shape. Therefore, the plurality of rigid patterns 491, 492, 493, and 494 is disposed in the non-active area NA which encloses the active area AA on the lower substrate 110. The plurality of rigid patterns 491, 492, 493, and 494 is disposed along the non-active area NA to be disposed in all the upper, lower, left, and right non-active areas NA of the display device 400 to enclose the active area AA. For example, the plurality of rigid patterns 491, 492, 493, and 494 may be disposed in the non-active area NA to have a rectangular ring shape which encloses the active area AA, but is not limited thereto.

The rigid unit 490 includes a first rigid pattern 491, a second rigid pattern 492, a third rigid pattern 493, and a fourth rigid pattern 494. The first rigid pattern 491 overlaps with the end of the cathode CA, the second rigid pattern 492 overlaps with an end of the encapsulation substrate 180, and the third rigid pattern 493 is disposed between the first rigid pattern 491 and the second rigid pattern 492. The fourth rigid pattern 494 is disposed at the outside from the second rigid pattern 492. A plurality of fourth rigid patterns 494 may be provided, but is not limited thereto. As an example, a plurality of third rigid patterns 493 may be provided, but is not limited thereto.

The first rigid pattern 491 is disposed to overlap with an end of the cathode CA and the second rigid pattern 492 is disposed to overlap with an end of the encapsulation substrate 180. The fourth rigid pattern 494 disposed at the outermost side, among the fourth rigid patterns 494, is disposed to overlap with an end of the lower substrate 110. Specifically, the first rigid pattern 491 which is disposed at the innermost side closest to the active area AA, among the plurality of rigid patterns 491, 492, 493, and 494, is disposed to overlap with the end of the cathode CA. Further, the fourth rigid pattern 494 which is disposed at the outermost side closest to the end of the lower substrate 110, among the plurality of rigid patterns 491, 492, 493, and 494, is disposed to overlap with the end of the lower substrate 110. Further, the second rigid pattern 492 is disposed to overlap with an end of the encapsulation substrate 180. Further, the third rigid pattern 493 may be disposed between the first rigid pattern 491 and the second rigid pattern 492, but may be omitted depending on the design.

The inner side of the first rigid pattern 491 is disposed to be closer to the active area AA than the end of the cathode CA and the outer side of the first rigid pattern 491 is disposed to be farther from the active area AA than the end of the cathode CA. The inner side of the second rigid pattern 492 is disposed to be closer to the active area AA than the end of the encapsulation substrate 180 and the outer side of the second rigid pattern 492 is disposed to be farther from the active area AA than the end of the encapsulation substrate 180. A plurality of fourth rigid patterns 494 is disposed at the outside from the second rigid pattern 492 and a fourth rigid pattern 492 which is disposed at the outermost side, among the plurality of fourth rigid patterns 492, is disposed to overlap with an end of the lower substrate 110. That is, the rigid unit 490 is disposed in an area overlapping with the end of the cathode CA and the end of the encapsulation substrate 180, an area between areas overlapping with the end of the encapsulation substrate 180 and the end of the lower substrate 110, and an area overlapping with the end of the lower substrate 110.

In the display device 400 according to still another exemplary aspect of the present disclosure, the rigid unit 490 is disposed in the outer peripheral area to improve the rigidity of the outer peripheral area. Specifically, the rigid unit 490 is disposed to overlap with an end of the upper substrate 180 in which the most creases are generated after the LLO process and creases or cracks are generated by being dented by a relatively strong upper substrate 180. Further, the rigid unit 490 is disposed in the entire outer peripheral area with respect to an area in which the cathode CA in which creases are not generated is disposed to provide the rigidity to the entire outer peripheral area of the display device 400. Therefore, in the display device 400 according to still another exemplary aspect of the present disclosure, the rigidity of the outer peripheral area is improved by means of the rigid unit 490 and the creases or cracks generated in the outer peripheral area of the display device 400 after the LLO process may be reduced or minimized. Therefore, the reliability of the display device 400 may be improved.

In the display device 400 according to still another exemplary aspect of the present disclosure, the rigid unit 490 includes a plurality of rigid patterns 491, 492, 493, and 494 which is spaced apart from each other to reduced or minimize a parasitic capacitance which may be generated by the rigid unit 490 while ensuring the rigidity of the outer peripheral area. As described above, in the non-active area, conductive components, such as a gate driver, other circuits, and wiring lines are disposed. At this time, when the rigid unit 490 is formed of a metal material, a parasitic capacitance between the above-described conductive components and the rigid unit 490 may be generated. The parasitic capacitance may be increased as an overlapping area of the conductive component and the rigid unit 490 is increased. Therefore, in the display device 400 according to still another exemplary aspect of the present disclosure, the rigid unit 490 includes a plurality of rigid patterns 491, 492, 493, and 494 which is spaced apart from each other to reduced or minimize an area in which the rigid unit 490 and the conductive components overlap with each other. Accordingly, the rigidity of the outer peripheral area is improved and the parasitic capacitance generated by the rigid unit 490 is reduced or minimized to improve the reliability of the display device 400.

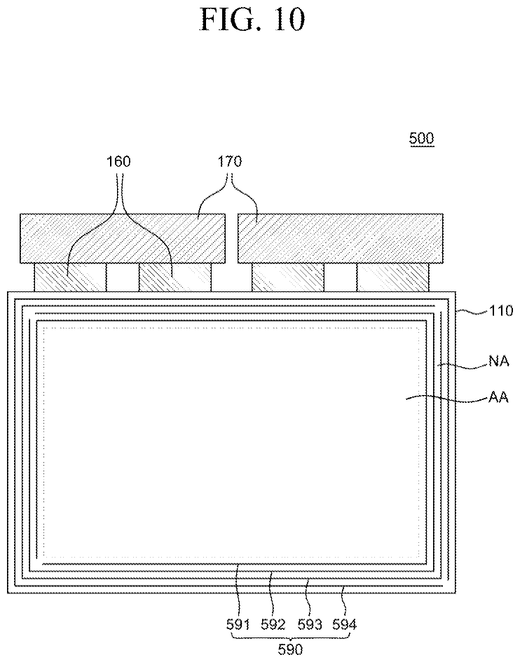

FIG. 10 is a plan view of a display device according to still another exemplary aspect of the present disclosure. The other configuration of a display device 500 of FIG. 10 excluding a rigid unit 590 is substantially the same as the display device 100 of FIGS. 1 to 6, so that a redundant description will be omitted or briefly given.

Referring to FIG. 10, the rigid unit 590 is disposed in the non-active area NA which encloses the active area AA on the lower substrate 110 and includes a plurality of rigid patterns 591, 592, 593, and 594 which is spaced apart from each other.

Each of the plurality of rigid patterns 591, 592, 593, and 594 is disposed along the non-active area NA to be disposed in all the upper, lower, left, and right non-active areas NA of the display device 500 to enclose the active area AA. For example, the rigid unit 590 may be disposed in the non-active area NA to have a square shape which encloses the active area AA. Embodiments are not limited thereto. As an example, the rigid unit 590 may be disposed in the non-active area NA to have a shape corresponding to the shape of the active area AA or the shape of the display device 500, which for example could be a circular shape, an oval shape, a quadrangle shape, a polygon shape, etc.

Each of the plurality of rigid patterns 591, 592, 593, and 594 has an open curve shape. The plurality of rigid patterns 591, 592, 593, and 594 is disposed along the non-active area NA and is disposed to enclose the active area AA. At this time, one end and the other end of each of the plurality of rigid patterns 591, 592, 593, and 594 are spaced apart from each other so that a partially open portion is disposed. Embodiments are not limited thereto. As an example, at least one of the plurality of rigid patterns 591, 592, 593, and 594 may have a closed curve shape.

One end and the other end of each of the plurality of rigid patterns 591, 592, 593, and 594 are spaced apart from each other. At this time, a location in which one end and the other end of each of the plurality of rigid patterns 591, 592, 593, and 594 are spaced apart from each other corresponds to a corner of each of the lower substrate 110, without being limited thereto. As an example, a location in which one end and the other end of each of the plurality of rigid patterns 591, 592, 593, and 594 are spaced apart from each other may be different in each of the plurality of rigid patterns 591, 592, 593, and 594. Specifically, as illustrated in FIG. 10, one end and the other end of the first rigid pattern 591 are disposed in a left lower corner of the lower substrate 110 to be spaced apart from each other. As illustrated in FIG. 10, one end and the other end of the second rigid pattern 592 are disposed at a left upper corner of the lower substrate 110 to be spaced apart from each other. As illustrated in FIG. 10, one end and the other end of the third rigid pattern 593 are disposed in a right upper corner of the lower substrate 110 to be spaced apart from each other. As illustrated in FIG. 10, one end and the other end of the fourth rigid pattern 594 are disposed in a right lower corner of the lower substrate 110 to be spaced apart from each other. Therefore, the first rigid pattern 591 has an open curve shape at the left lower corner of the lower substrate 110 and the second rigid pattern 592 has an open curve shape at the left upper corner of the lower substrate 110. The third rigid pattern 593 has an open curve shape at the right upper corner of the lower substrate 110 and the fourth rigid pattern 594 has an open curve shape in the right lower corner of the lower substrate 110. However, if the location in which one end and the other end of each of the plurality of rigid patterns 591, 592, 593, and 594 which are spaced apart from each other is different, it is not limited to the example illustrated in FIG. 10.

In the display device 500 according to still another exemplary aspect of the present disclosure, the rigid patterns 591, 592, 593, and 594 of the rigid unit 590 is disposed in the outer peripheral area to improve the rigidity of the outer peripheral area. Specifically, the rigid unit 590 includes a plurality of rigid patterns 591, 592, 593, and 594 which is spaced apart from each other to reduce or minimize the parasitic capacitance which may be caused by the rigid unit 590 while ensuring the rigidity of the outer peripheral area. As described above, in the non-active area NA, conductive components, such as a gate driver, other circuits, and wiring lines are disposed. At this time, when the rigid unit 590 is formed of a metal material, a parasitic capacitance between the above-described conductive components and the rigid unit 590 may be generated. The parasitic capacitance may be increased as an overlapping area of the conductive component and the rigid unit is increased. Therefore, in the display device 500 according to still another exemplary aspect of the present disclosure, the rigid unit 590 includes a plurality of rigid patterns 591, 592, 593, and 594 which is spaced apart from each other to reduce or minimize an area in which the rigid unit 590 and the conductive components overlap with each other. Accordingly, the rigidity of the outer peripheral area is improved and the parasitic capacitance generated by the rigid unit 590 is reduce or minimized to improve the reliability of the display device 500.

In the meantime, the display device 500 according to still another exemplary aspect of the present disclosure may be implemented as a rollable display device. When the display device 500 is implemented as a rollable display device, the display device 500 may be wound around or unwound from a roller in a vertical direction with respect to FIG. 10. At this time, a stress is concentrated in a corner portion of the display device 500 more than upper, lower, left, and right sides of the display device 500 so that the plurality of rigid patterns 591, 592, 593, and 594 may be cracked. Therefore, in the display device 500 according to still another exemplary aspect of the present disclosure, one end and the other end of each of the plurality of rigid patterns 591, 592, 593, and 594 are spaced apart from each other in each corner of the lower substrate 110. Therefore, the cracks of the plurality of rigid patterns 591, 592, 593, and 594 which may be generated during the process of winding and unwinding the display device 500 are suppressed and the propagation of the cracks generated from the plurality of rigid patterns 591, 592, 593, and 594 to the other components may be suppressed.

Therefore, in the display device 500 according to still another exemplary aspect of the present disclosure, a spaced location of one end and the other end of each of the plurality of rigid patterns 591, 592, 593, and 594 is different in each of the plurality of rigid patterns 591, 592, 593, and 594. If one end and the other end of each of the plurality of rigid patterns are spaced apart from each other in the same corner of the lower substrate 110, there may be an area in a corner in which all the plurality of rigid patterns 591, 592, 593, and 594 is not disposed. In this case, the creases are generated in the corresponding outer peripheral area. Thereafter, when a subsequent process, such as a process of laminating the polarizer 150 and a process of attaching a back cover, is performed, the crack may be caused in the corresponding outer peripheral area. Therefore, in the display device 500 according to still another exemplary aspect of the present disclosure, a spaced location of one end and the other end of each of the plurality of rigid patterns 591, 592, 593, and 594 is different in each of the plurality of rigid patterns 591, 592, 593, and 594. Therefore, the creases or cracks generated in the corner area may be reduced or minimized to improve the reliability of the display device 100.

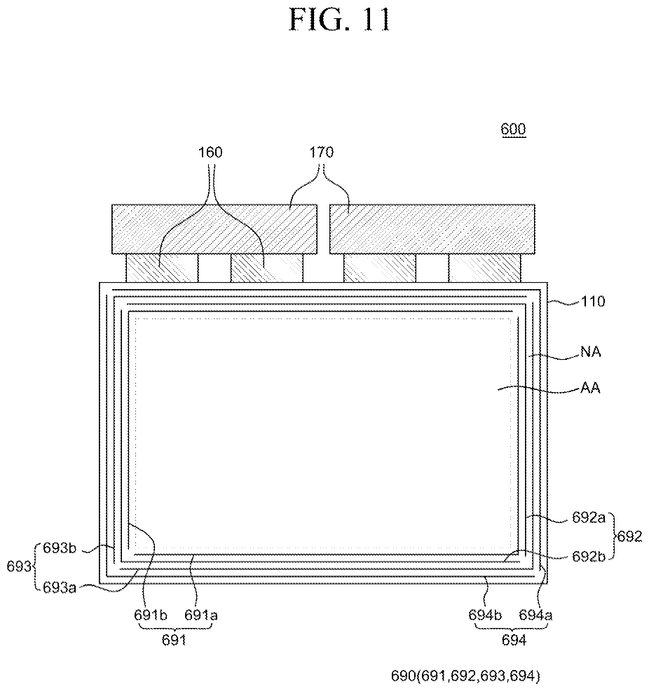

FIG. 11 is a plan view of a display device according to still another exemplary aspect of the present disclosure. The other configuration of a display device 600 of FIG. 11 excluding a rigid unit 690 is substantially the same as the display device 500 of FIG. 10, so that a redundant description will be omitted or briefly given.

Referring to FIG. 11, the rigid unit 690 is disposed in the non-active area NA which encloses the active area AA on the lower substrate 110 and includes a plurality of rigid patterns 691, 692, 693, and 694 which is spaced apart from each other.

Each of the plurality of rigid patterns 691, 692, 693, and 694 is disposed along the non-active area NA to be disposed in all the upper, lower, left, and right non-active areas NA of the display device 600 to enclose the active area AA. For example, the rigid unit 690 may be disposed in the non-active area NA to have a square shape which encloses the active area AA.

Further, each of the plurality of rigid patterns 691, 692, 693, and 694 may have an open curve shape. Each of the plurality of rigid patterns 691, 692, 693, and 694 includes a plurality of sub patterns 691a, 691b, 692a, 692b, 693a, 693b, 694a, and 694b which is spaced apart from each other. The location in which the plurality of sub patterns 691a, 691b, 692a, 692b, 693a, 693b, 694a, and 694b is spaced apart from each other is disposed in corners of the lower substrate 110. Specifically, the first rigid pattern 691 includes a first sub pattern 691a and a second sub pattern 691b which are spaced apart from each other. The location in which the first sub pattern 691a and the second sub pattern 691b are spaced apart from each other may be disposed in a left lower corner and a right upper corner of the lower substrate 110, as illustrated in FIG. 11. The second rigid pattern 692 includes a first sub pattern 692a and a second sub pattern 692b which are spaced apart from each other. The location in which the first sub pattern 692a and the second sub pattern 692b are spaced apart from each other may be disposed in a left upper corner and a right lower corner of the lower substrate 110, as illustrated in FIG. 11. The third rigid pattern 693 includes a first sub pattern 693a and a second sub pattern 693b which are spaced apart from each other. The location in which the first sub pattern 693a and the second sub pattern 693b are spaced apart from each other may be disposed in a right upper corner and a left lower corner of the lower substrate 110, as illustrated in FIG. 11. The fourth rigid pattern 694 includes a first sub pattern 694a and a second sub pattern 694b which are spaced apart from each other. The location in which the first sub pattern 694a and the second sub pattern 694b are spaced apart from each other may be disposed in a left upper corner and a right lower corner of the lower substrate 110, as illustrated in FIG. 11. In the meantime, in FIG. 11, it is illustrated that the plurality of rigid patterns 691, 692, 693, and 694 includes two sub patterns 691a, 691b, 692a, 692b, 693a, 693b, 694a, and 694b. However, the number of sub patterns 691a, 691b, 692a, 692b, 693a, 693b, 694a, and 694b included in each of the plurality of rigid patterns 691, 692, 693, and 694 is not limited thereto. In addition, the location in which the plurality of sub patterns 691a, 691b, 692a, 692b, 693a, 693b, 694a, and 694b is spaced apart from each other is not limited thereto. As an example, the location in which the plurality of sub patterns 691a, 691b, 692a, 692b, 693a, 693b, 694a, and 694b is spaced apart from each other is different in the plurality of rigid patterns 691, 692, 693, and 694.

In the display device 600 according to still another exemplary aspect of the present disclosure, the rigid patterns 691, 692, 693, and 694 of the rigid unit 690 is disposed in the outer peripheral area to improve the rigidity of the outer peripheral area. Specifically, the rigid unit 690 includes a plurality of rigid patterns 691, 692, 693, and 694 which is spaced apart from each other to reduce or minimize the parasitic capacitance which may be caused by the rigid unit 690 while ensuring the rigidity of the outer peripheral area. As described above, in the non-active area NA, conductive components, such as a gate driver, other circuits, and wiring lines, are disposed. At this time, when the rigid unit 690 is formed of a metal material, a parasitic capacitance between the above-described conductive components and the rigid unit 690 may be generated. The parasitic capacitance may be increased as an overlapping area of the conductive component and the rigid unit 690 is increased. Therefore, in the display device 600 according to still another exemplary aspect of the present disclosure, the rigid unit 690 includes a plurality of rigid patterns 691, 692, 693, and 694 which is spaced apart from each other to reduce or minimize an area in which the rigid unit 690 and the conductive components overlap with each other. Accordingly, the rigidity of the outer peripheral area is improved and the parasitic capacitance generated by the rigid unit 690 is reduced or minimized to improve the reliability of the display device 600.

In the display device 600 according to still another exemplary aspect of the present disclosure, each of the plurality of rigid patterns 691, 692, 693, and 694 includes a plurality of sub patterns 691a, 691b, 692a, 692b, 693a, 693b, 694a, and 694b which is spaced apart from each other. The location in which the plurality of sub patterns 691a, 691b, 692a, 692b, 693a, 693b, 694a, and 694b is spaced apart from each other is disposed in corners of the lower substrate 110. Therefore, the cracks of the plurality of rigid patterns 691, 692, 693, and 694 which may be generated in the corner of the lower substrate 110 in which the stress is concentrated during the process of winding and unwinding the display device 600 may be suppressed. Further, the propagation of the cracks generated from the plurality of rigid patterns 691, 692, 693, and 694 to the other components may be suppressed.

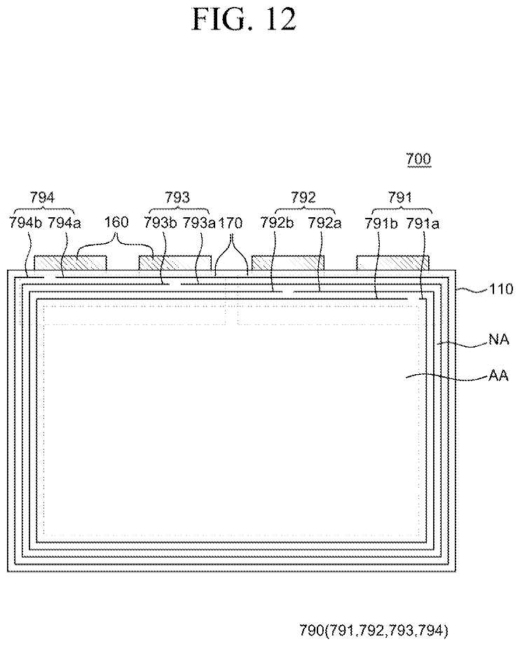

FIG. 12 is a plan view of a display device according to still another exemplary aspect of the present disclosure. The other configuration of a display device 700 of FIG. 12 excluding a rigid unit 790 is substantially the same as the display device 500 of FIG. 10, so that a redundant description will be omitted or briefly given.

Referring to FIG. 12, a printed circuit board 170 may be located on a rear surface of the lower substrate 110. Specifically, the flexible film 160 is bent so that the printed circuit board 170 may be located on the rear surface of the lower substrate 110. Therefore, the printed circuit board 170 may be disposed to overlap with one side of the lower substrate 110.

Referring to FIG. 12, the rigid unit 790 is disposed in the non-active area NA which encloses the active area AA on the lower substrate 110 and includes a plurality of rigid patterns 791, 792, 793, and 794 which is spaced apart from each other.

Each of the plurality of rigid patterns 791, 792, 793, and 794 is disposed along the non-active area NA to be disposed in all the upper, lower, left, and right non-active areas NA of the display device 700 to enclose the active area AA. For example, the rigid unit 790 may be disposed in the non-active area NA to have a rectangular ring shape which encloses the active area AA.

Further, each of the plurality of rigid patterns 791, 792, 793, and 794 may have an open curve shape. Each of the plurality of rigid patterns 791, 792, 793, and 794 includes a plurality of sub patterns 791a, 791b, 792a, 792b, 793a, 793b, 794a, and 794b which is spaced apart from each other. The location in which the plurality of sub patterns 791a, 791b, 792a, 792b, 793a, 793b, 794a, and 794b is spaced apart from each other is disposed in an area overlapping with the printed circuit board 170. Specifically, the first rigid pattern 791 includes a first sub pattern 791a and a second sub pattern 791b which are spaced apart from each other. The location in which the first sub pattern 791a and the second sub pattern 791b are spaced apart from each other is disposed in the non-active area NA in an upper portion of the lower substrate 110 which is an overlapping area when the flexible film 160 is bent to dispose the printed circuit board 170 on the rear surface of the lower substrate 110, as illustrated in FIG. 12. The second rigid pattern 792 includes a first sub pattern 792a and a second sub pattern 792b which are spaced apart from each other. The location in which the first sub pattern 792a and the second sub pattern 792b are spaced apart from each other is disposed in the non-active area NA in an upper portion of the lower substrate 110 which is an overlapping area when the flexible film 160 is bent to dispose the printed circuit board 170 on the rear surface of the lower substrate 110, as illustrated in FIG. 12. The third rigid pattern 793 includes a first sub pattern 793a and a second sub pattern 793b which are spaced apart from each other. The location in which the first sub pattern 793a and the second sub pattern 793b are spaced apart from each other is disposed in the non-active area NA in an upper portion of the lower substrate 110 which is an overlapping area when the flexible film 160 is bent to dispose the printed circuit board 170 on the rear surface of the lower substrate 110, as illustrated in FIG. 12. The fourth rigid pattern 794 includes a first sub pattern 794a and a second sub pattern 794b which are spaced apart from each other. The location in which the first sub pattern 794a and the second sub pattern 794b are spaced apart from each other is disposed in the non-active area NA in an upper portion of the lower substrate 110 which is an overlapping area when the flexible film 160 is bent to dispose the printed circuit board 170 on the rear surface of the lower substrate 110, as illustrated in FIG. 12. In the meantime, in FIG. 12, it is illustrated that the plurality of rigid patterns 791, 792, 793, and 794 includes two sub patterns 791a, 791b, 792a, 792b, 793a, 793b, 794a, and 794b. However, the number as well as location of sub patterns 791a, 791b, 792a, 792b, 793a, 793b, 794a, and 794b included in each of the rigid patterns 791, 792, 793, and 794 is not limited thereto.

In the display device 700 according to still another exemplary aspect of the present disclosure, the rigid patterns 791, 792, 793, and 794 of the rigid unit 790 is disposed in the outer peripheral area to improve the rigidity of the outer peripheral area. Specifically, the rigid unit 790 includes a plurality of rigid patterns 791, 792, 793, and 794 which is spaced apart from each other to reduce or minimize the parasitic capacitance which may be caused by the rigid unit 790 while ensuring the rigidity of the outer peripheral area. As described above, in the non-active area NA, conductive components, such as a gate driver, other circuits, and wiring lines are disposed. At this time, when the rigid unit 790 is formed of a metal material, a parasitic capacitance between the above-described conductive components and the rigid unit 790 may be generated. The parasitic capacitance may be increased as an overlapping area of the conductive component and the rigid unit 790 is increased. Therefore, in the display device 700 according to still another exemplary aspect of the present disclosure, the rigid unit 790 includes a plurality of rigid patterns 791, 792, 793, and 794 which is spaced apart from each other to reduce or minimize an area in which the rigid unit 790 and the conductive components overlap with each other. Accordingly, the rigidity of the outer peripheral area is improved and the parasitic capacitance generated by the rigid unit 790 is reduced or minimized to improve the reliability of the display device 700.

Further, in the display device 700 according to still another exemplary aspect of the present disclosure, each of the plurality of rigid patterns 791, 792, 793, and 794 includes a plurality of sub patterns 791a, 791b, 792a, 792b, 793a, 793b, 794a, and 794b which is spaced apart from each other. The location in which the plurality of sub patterns 791a, 791b, 792a, 792b, 793a, 793b, 794a, and 794b is spaced apart from each other is disposed in the non-active area NA in an upper portion of the lower substrate 110 which is an overlapping area when the flexible film 160 is bent to dispose the printed circuit board 170 on the rear surface of the lower substrate 110. Therefore, the flexible film 160 which is not rolled during the process of winding and unwinding the display device 700 is bent to dispose the printed circuit board 170 on the rear surface of the lower substrate 110. At this time, the location in which the plurality of sub patterns 791a, 791b, 792a, 792b, 793a, 793b, 794a, and 794b is spaced apart from each other is disposed in the non-active area NA in an upper portion of the lower substrate 110 which is an area overlapping. Therefore, the cracks of the plurality of rigid patterns 791, 792, 793, and 794 which may be generated during the process of winding and unwinding the display device 700 are suppressed and the propagation of the cracks generated from the plurality of rigid patterns 791, 792, 793, and 794 to the other components may be suppressed.

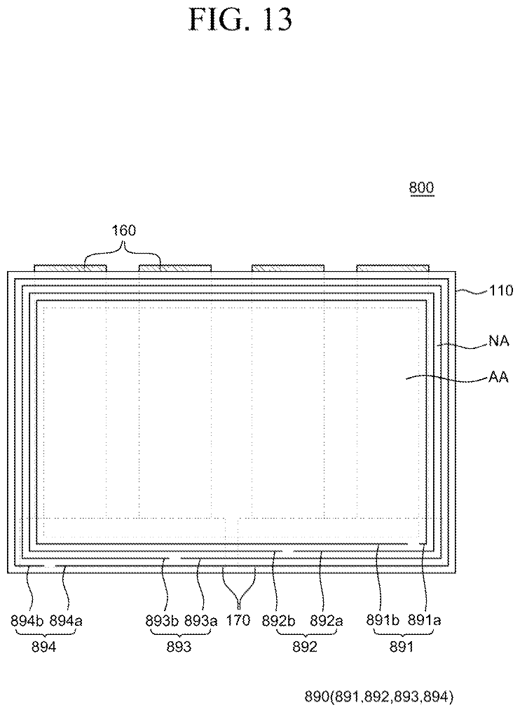

FIG. 13 is a plan view of a display device according to still another exemplary aspect of the present disclosure. The other configuration of a display device 800 of FIG. 13 excluding a rigid unit 890 is substantially the same as the display device 500 of FIG. 10, so that a redundant description will be omitted or briefly given.

Referring to FIG. 13, a printed circuit board 170 may be located on a rear surface of the lower substrate 110. Specifically, the flexible film 160 is bent so that the printed circuit board 170 may be located on the rear surface of the lower substrate 110. Therefore, the printed circuit board 170 may be disposed to overlap with one side of the lower substrate 110.

Referring to FIG. 13, a rigid unit 890 is disposed in the non-active area NA which encloses the active area AA on the lower substrate 110 and includes a plurality of rigid patterns 891, 892, 893, and 894 which is spaced apart from each other.

Each of the plurality of rigid patterns 891, 892, 893, and 894 is disposed along the non-active area NA to be disposed in all the upper, lower, left, and right non-active areas NA of the display device 800 to enclose the active area AA. For example, the rigid unit 890 may be disposed in the non-active area NA to have a square shape which encloses the active area AA.

Further, each of the plurality of rigid patterns 891, 892, 893, and 894 may have an open curve shape. Each of the plurality of rigid patterns 891, 892, 893, and 894 includes a plurality of sub patterns 891a, 891b, 892a, 892b, 893a, 893b, 894a, and 894b which is spaced apart from each other. The location in which the plurality of sub patterns 891a, 891b, 892a, 892b, 893a, 893b, 894a, and 894b is spaced apart from each other is disposed in an area overlapping with the printed circuit board 170. Specifically, the first rigid pattern 891 includes a first sub pattern 891a and a second sub pattern 891b which are spaced apart from each other. The location in which the first sub pattern 891a and the second sub pattern 891b are spaced apart from each other is disposed in the non-active area NA in a lower portion of the lower substrate 110 which is an area overlapping when the flexible film 160 is bent to dispose the printed circuit board 170 on the rear surface of the lower substrate 110, as illustrated in FIG. 13. The second rigid pattern 892 includes a first sub pattern 892a and a second sub pattern 892b which are spaced apart from each other. The location in which the first sub pattern 892a and the second sub pattern 892b are spaced apart from each other is disposed in the non-active area NA in a lower portion of the lower substrate 110 which is an area overlapping when the flexible film 160 is bent to dispose the printed circuit board 170 on the rear surface of the lower substrate 110, as illustrated in FIG. 13. The third rigid pattern 893 includes a first sub pattern 893a and a second sub pattern 893b which are spaced apart from each other. The location in which the first sub pattern 893a and the second sub pattern 893b are spaced apart from each other is disposed in the non-active area NA in a lower portion of the lower substrate 110 which is an area overlapping when the flexible film 160 is bent to dispose the printed circuit board 170 on the rear surface of the lower substrate 110. The fourth rigid pattern 894 includes a first sub pattern 894a and a second sub pattern 894b which are spaced apart from each other. The location in which the first sub pattern 894a and the second sub pattern 894b are spaced apart from each other is disposed in the non-active area NA in a lower portion of the lower substrate 110 which is an area overlapping when the flexible film 160 is bent to dispose the printed circuit board 170 on the rear surface of the lower substrate 110. In the meantime, in FIG. 13, it is illustrated that the plurality of rigid patterns 891, 892, 893, and 894 includes two sub patterns 891a, 891b, 892a, 892b, 893a, 893b, 894a, and 894b. However, the number of sub patterns 891a, 891b, 892a, 892b, 893a, 893b, 894a, and 894b included in each of the plurality of rigid patterns 891, 892, 893, and 894 is not limited thereto.

In the display device 800 according to still another exemplary aspect of the present disclosure, the rigid patterns 891, 892, 893, and 894 of the rigid unit 890 is disposed in the outer peripheral area to improve the rigidity of the outer peripheral area. Specifically, the rigid unit 890 includes a plurality of rigid patterns 891, 892, 893, and 894 which is spaced apart from each other to reduce or minimize the parasitic capacitance which may be caused by the rigid unit 890 while ensuring the rigidity of the outer peripheral area. As described above, in the non-active area NA, conductive components, such as a gate driver, other circuits, and wiring lines are disposed. At this time, when the rigid unit 890 is formed of a metal material, a parasitic capacitance between the above-described conductive components and the rigid unit 890 may be generated. The parasitic capacitance may be increased as an overlapping area of the conductive component and the rigid unit 890 may be increased. Therefore, in the display device 800 according to still another exemplary aspect of the present disclosure, the rigid unit 890 includes a plurality of rigid patterns 891, 892, 893, and 894 which is spaced apart from each other to reduce or minimize an area in which the rigid unit 890 and the conductive components overlap with each other. Accordingly, the rigidity of the outer peripheral area is improved and the parasitic capacitance generated by the rigid unit 890 is reduced or minimized to improve the reliability of the display device 800.

Further, in the display device 800 according to still another exemplary aspect of the present disclosure, each of the plurality of rigid patterns 891, 892, 893, and 894 includes a plurality of sub patterns 891a, 891b, 892a, 892b, 893a, 893b, 894a, and 894b which is spaced apart from each other. The location in which the plurality of sub patterns 891a, 891b, 892a, 892b, 893a, 893b, 894a, and 894b is spaced apart from each other is disposed in the non-active area NA in a lower portion of the lower substrate 110 overlapping when the flexible film 160 is bent to dispose the printed circuit board 170 on the rear surface of the lower substrate 110. Therefore, the flexible film 160 which is not rolled during the process of winding and unwinding the display device 800 is bent to dispose the printed circuit board 170 on the rear surface of the lower substrate 110. At this time, the location in which the plurality of sub patterns 891a, 891b, 892a, 892b, 893a, 893b, 894a, and 894b is spaced apart from each other is disposed in the non-active area NA in an upper portion of the lower substrate 110 which is an area overlapping with each other. Therefore, the cracks of the plurality of rigid patterns 891, 892, 893, and 894 which may be generated during the process of winding and unwinding the display device 800 may be suppressed and the propagation of the cracks generated from the plurality of rigid patterns 891, 892, 893, and 894 to the other components may be suppressed.

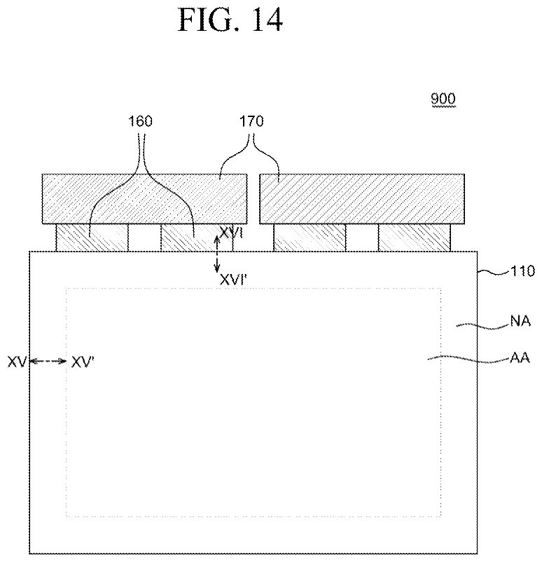

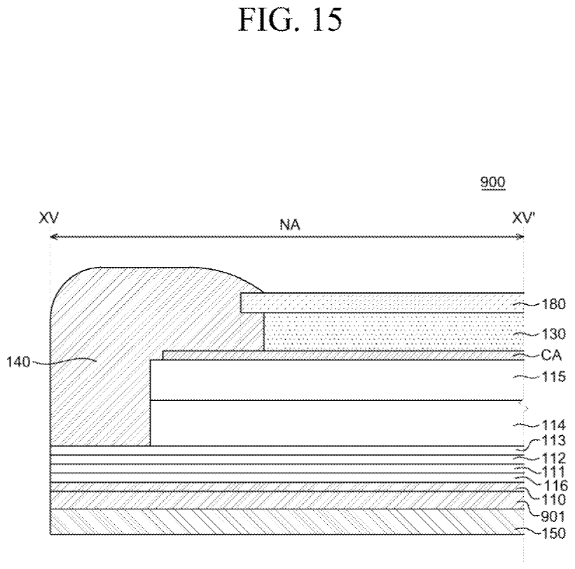

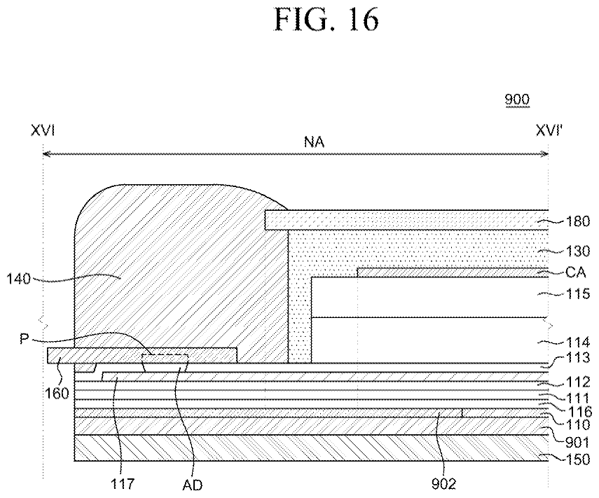

FIG. 14 is a plan view of a display device according to still another exemplary aspect of the present disclosure. FIG. 15 is a cross-sectional view taken along line XVI-XVI′ of FIG. 14 according to an exemplary embodiment of the present disclosure. FIG. 16 is a cross-sectional view taken along line XV-XV′ of FIG. 14 according to an exemplary embodiment of the present disclosure. Other configuration of a display device 800 of FIGS. 14 to 16 excluding a cathode CA, a rigid unit 990, a lower substrate 110, and a protection member 901 is substantially the same as the display device 500 of FIG. 10 so that a redundant description will be omitted or briefly given.

A non-active area NA illustrated in FIG. 15 is a remaining non-active area NA excluding one side to which the flexible film 160 is connected.

Referring to FIG. 15, the cathode CA is disposed to overlap with an end of the encapsulation substrate 180. The cathode CA overlaps with an end of the encapsulation substrate 180 in remaining side portions other than one side of the lower substrate 110 to which the flexible film 160 is connected. Specifically, the end of the cathode CA is disposed to be closer to an end of the lower substrate 110 than an end of the encapsulation substrate 180.

The planarization layer 114 and the bank 115 disposed below the cathode CA is disposed to overlap with the end of the encapsulation substrate 180. For example, the planarization layer 114 and the bank 115 may be disposed to be closer to the end of the lower substrate 110 than the end of the cathode CA.

A seal member 140 is disposed to enclose a part of a top surface of the cathode CA and side surfaces of the cathode CA, the planarization layer 114, and the bank 115. The seal member 140 is disposed to enclose side surfaces of the cathode CA, the planarization layer 114, and the bank 115 to reduce or minimize moisture permeation through side surfaces of the cathode CA, the planarization layer 114, and the bank 115. For example, the seal member 140 may be disposed to cover a side surface of the encapsulation layer 130, a part of a top surface and a side surface of the encapsulation substrate 180, a part of a top surface of the cathode CA, and side surfaces of the cathode CA, the planarization layer 114, and the bank 115.

A protection member 901 is disposed below the lower substrate 110. The protection member 901 is disposed on the entire lower portion of the lower substrate 110. For example, the protection member 901 may be disposed to be in contact with the entire bottom surface of the lower substrate 110. At this time, the protection member 901 may be formed of a non-conductive material having elasticity to supplement a rigidity of the lower substrate 110. Further, the protection member 901 may be formed of a material having an adhesiveness. For example, the protection member 901 may be formed of polyimide (PI), poly urethane, epoxy, or acryl based material, but is not limited thereto.

A non-active area NA illustrated in FIG. 16 is a non-active area NA in one side to which the flexible film 160 is connected.

Referring to FIG. 16, in the display device 900, a link line 117 is disposed on the lower substrate 110. The link line 117 extends from the active area AA to the non-display area NA. For example, one end of the link line 117 is connected to the plurality of sub pixels of the active area AA and the other end may be connected to the pad disposed in the non-active area NA. For example, the link line 117 may be disposed on the gate insulating layer 112 and the passivation layer 113 may be disposed above the link line 117. At this time, in the pad connected to the link line 117, the passivation layer 113 is open to be exposed and the pad connected to the link line 117 is electrically connected to a pad P disposed in the flexible film 160 by means of a conductive adhesive member AD disposed in the exposed pad. A rigid unit 902 is disposed in the non-active area NA of one side to which the flexible film 160 is connected. For example, the rigid unit 902 may be disposed only in the non-active area NA in one side to which the flexible film 160 is connected, with a predetermined width.

The rigid unit 902 is disposed on the same layer as the lower substrate 110 in one side of the lower substrate 110. For example, the lower substrate 110 is disposed to a part of the non-active area NA and the rigid unit 902 may be disposed in the remaining non-active area NA in which the lower substrate 110 is not disposed Embodiments are not limited thereto. As an example, the rigid unit 902 may be disposed on a different layer from the lower substrate 110 in one side of the lower substrate 110. As an example, the rigid unit 902 may be disposed to overlap a portion of the lower substrate 110.

The rigid unit 902 is disposed to overlap with an end of the cathode CA and an end of the encapsulation substrate 180.

An inner side of the rigid unit 902 is disposed to overlap with an end of the cathode CA and an outer side of the rigid unit 902 is disposed to overlap with an end of the encapsulation substrate 180. For example, an inner side of the rigid unit 190 is disposed inside from the location in which the rigid unit 902 and the end of the cathode CA overlap with to be in contact with one end surface of the lower substrate 110 and an outer side of the rigid unit 902 may be disposed to the end of the protection member 901.

The rigid unit 902 is formed of a material having rigidity to ensure the rigidity in the outer peripheral area of the display device 900. For example, the rigid unit 902 may be formed of ceramic or a metal material. When the rigid unit 902 is formed of ceramic, the ceramic is not a conductive material so that a parasitic capacitance with various conductive components which may be disposed above the rigid unit 902 may be reduced. Further, when the rigid unit 902 is formed of a metal material, the rigid unit 902 blocks laser used for the LLO process to suppress the damage of other configurations above the rigid unit 902 and provide a higher rigidity than the ceramic.

In the display device 900 according to still another exemplary aspect of the present disclosure, the cathode CA is disposed to extend to an end direction of the lower substrate 110 in the remaining non-active area NA excluding one side of the lower substrate 110 in which the flexible film 160 is disposed. Specifically, the cathode CA is disposed to overlap with an end of the upper substrate 180 in which the most creases are generated after the LLO process and creases or cracks are generated by being dented by a relatively strong upper substrate 180. By doing this, the rigidity of the outer peripheral area may be improved. Therefore, in the display device 900 according to still another exemplary aspect of the present disclosure, the rigidity of the outer peripheral area is improved by means of the cathode CA which is disposed to overlap with the end of the upper substrate 180. The creases or cracks generated in the outer peripheral area of the display device 900 after the LLO process may be reduced or minimized. Therefore, the reliability of the display device 900 may be improved.

Further, in the display device 900 according to another exemplary aspect of the present disclosure, the protection member 901 is disposed below the lower substrate 110 to suppress the generation and the progress of the crack. Specifically, the protection member 901 which is formed of a non-conductive material having the elasticity is disposed on the entire lower surface of the lower substrate 110 to release the impact during the manufacturing process. Therefore, the crack generated during the manufacturing process of the display device 900 after the LLO process is reduced or minimized. Even though the cracks are generated, the progress of the cracks is reduced or minimized to improve the reliability of the display device 900.

Further, in the display device 900 according to still another exemplary aspect of the present disclosure, the rigid unit 902 is disposed on the same layer as the lower substrate 110 in one side of the lower substrate 110 of the non-active area NA in which the flexible film 160 is disposed. By doing this, the rigidity of the outer peripheral area may be improved. Specifically, the rigid unit 902 is disposed to overlap with the end of the upper substrate 180 and the end of the cathode CA in which the most creases are generated after the LLO process and creases or cracks are generated by being dented by a relatively strong upper substrate 180. By doing this, the rigidity of the outer peripheral area may be improved. Therefore, in the display device 900 according to still another exemplary aspect of the present disclosure, the rigidity of the outer peripheral area is improved by means of the rigid unit 902 which is disposed to overlap with the end of the upper substrate 180 and the end of the cathode CA. The creases or cracks generated in the outer peripheral area of the display device 900 after the LLO process may be reduced or minimized. Therefore, the reliability of the display device 900 may be improved.

The exemplary aspects of the present disclosure may also be described as follows:

According to an aspect of the present disclosure, a display device includes a lower substrate which includes an active area including a plurality of sub pixels and a non-active area enclosing the active area and is formed of one of transparent conducting oxide and an oxide semiconductor layer, a rigid unit which is disposed in the non-active area on the lower substrate to enclose the active area, an insulating layer which is disposed on the lower substrate and the rigid unit, a cathode disposed on the insulating layer and an encapsulation substrate disposed on the cathode.

The rigid unit may overlap with an end of the cathode and an end of the encapsulation substrate.

An inner side of the rigid unit may be disposed to be closer to the active area than an end of the cathode and an outer side of the rigid unit is disposed to overlap with an end of the lower substrate.

The rigid unit may include a plurality of rigid patterns which is spaced apart from each other.

A first rigid pattern of the plurality of rigid patterns may overlap with an end of the cathode and a second rigid pattern of the plurality of rigid patterns may overlap with an end of the encapsulation substrate.

A third rigid pattern of the plurality of rigid patterns may be disposed between the first rigid pattern and the second rigid pattern.

A fourth rigid pattern of the plurality of rigid patterns may be disposed at the outside from the second rigid pattern.

Each of the plurality of rigid patterns may have a closed curve shape.

Each of the plurality of rigid patterns may have an open curve shape.

One end and the other end of the plurality of rigid patterns may be spaced apart from each other and a location in which one end and the other end of each of the plurality of rigid patterns may be spaced apart from each other is different for each of the plurality of rigid patterns.

The location in which one end and the other end of each of the plurality of rigid patterns may be spaced apart from each other is disposed in each corner of the lower substrate.

Each of the plurality of rigid patterns may include a plurality of sub patterns which is spaced apart from each other and a location in which the plurality of sub patterns is spaced apart from each other is disposed in a corner of the lower substrate.

The display device may further include a printed circuit board which is electrically connected to the lower substrate, wherein each of the plurality of rigid patterns includes a plurality of sub patterns which is spaced apart from each other and a location in which the plurality of sub patterns is spaced apart from each other is disposed in an area overlapping with the printed circuit board.

The rigid unit may be formed of ceramic or a metal material.

According to another aspect of the present disclosure, a display device includes a lower substrate which includes an active area and a non-active area and is formed of any one of transparent conducting oxide and an oxide semiconductor layer, a cathode disposed in the active area on the lower substrate, an encapsulation substrate which covers the cathode and a plurality of rigid patterns which is disposed on the lower substrate and is spaced apart from each other, wherein a first rigid pattern of the plurality of rigid patterns overlaps with an end of the cathode and a second rigid pattern of the plurality of rigid patterns overlaps an end of the encapsulation substrate.

One end and the other end of the plurality of rigid patterns may be spaced apart from each other and a location in which one end and the other end of each of the plurality of rigid patterns may be spaced apart from each other is disposed in each corner of the lower substrate.

Each of the plurality of rigid patterns may include a plurality of sub patterns which is spaced apart from each other and a location in which the plurality of sub patterns is spaced apart from each other is disposed in a corner of the lower substrate.

The display device may further include a printed circuit board which is electrically connected to the lower substrate, wherein each of the plurality of rigid patterns includes a plurality of sub patterns which is spaced apart from each other and a location in which the plurality of sub patterns is spaced apart from each other is disposed in an area overlapping with the printed circuit board.

According to still another aspect of the present disclosure, a display device includes a lower substrate which includes an active area including a plurality of sub pixels and a non-active area enclosing the active area and is formed of one of transparent conducting oxide and an oxide semiconductor layer, an insulating layer disposed on the lower substrate, a cathode disposed on the insulating layer and an encapsulation substrate disposed on the cathode, wherein the cathode overlaps with an end of the encapsulation substrate.

The display device may further include a flexible film disposed on one side of the lower substrate, wherein the cathode overlaps with an end of the encapsulation substrate in a side portion excluding one side of the lower substrate.

The display device may further include a rigid unit which is disposed on the same layer as the lower substrate in one side of the lower substrate.

An end of the cathode may be disposed to be closer to an end of the lower substrate than an end of the encapsulation substrate.

The display device may further include a protection member may be disposed below the lower substrate.

It will be apparent to those skilled in the art that various modifications and variations can be made in the display device of the present disclosure without departing from the spirit or scope of the aspects. Thus, it is intended that the present disclosure covers the modifications and variations of the aspects provided they come within the scope of the appended claims and their equivalents.

What is claimed is:

1. A display device, comprising:
a lower substrate which includes an active area including a plurality of sub pixels and a non-active area enclosing the active area and is formed of one of transparent conducting oxide and an oxide semiconductor layer;
a rigid unit disposed in the non-active area on the lower substrate that encloses the active area;
an insulating layer disposed on the lower substrate and the rigid unit;
a light emitting element on the insulating layer including a cathode.

2. The display device according to claim 1, wherein the rigid unit overlaps an end of the cathode.

3. The display device according to claim 1, further comprising an encapsulation substrate on the cathode.

4. The display device according to claim 5, wherein the rigid unit overlaps with an end of the cathode and an end of the encapsulation substrate.

5. The display device according to claim 4, wherein
an end of the cathode is disposed to be closer to the active area than an end of the encapsulation substrate, and
wherein an inner side of the rigid unit is disposed so as to be closer to the active area than the end of the cathode and an outer side of the rigid unit is disposed so as to be farther from the active area than the end of the encapsulation substrate.

6. The display device according to claim 3, wherein an inner side of the rigid unit is disposed to be closer to the active area than an end of the cathode and an outer side of the rigid unit overlaps with an end of the lower substrate.

7. The display device according to claim 3, wherein the rigid unit includes a plurality of rigid patterns which is spaced apart from each other, each of which at least partially encloses the active area.

8. The display device according to claim 7, wherein a first rigid pattern of the plurality of rigid patterns overlaps with an end of the cathode and a second rigid pattern of the plurality of rigid patterns overlaps with an end of the encapsulation substrate.

9. The display device according to claim 8, wherein a third rigid pattern of the plurality of rigid patterns is disposed between the first rigid pattern and the second rigid pattern.

10. The display device according to claim 8, wherein a fourth rigid pattern of the plurality of rigid patterns is disposed at the outside from the second rigid pattern.

11. The display device according to claim 7, wherein at least one of the plurality of rigid patterns has a closed curve shape.

12. The display device according to claim 7, wherein at least one of the plurality of rigid patterns has an open curve shape.

13. The display device according to claim 12, wherein one end and another end of the plurality of rigid patterns are spaced apart from each other and a location in which the one end and the another end of each of the plurality of rigid patterns are spaced apart from each other is different for each of the plurality of rigid patterns.

14. The display device according to claim 13, wherein the location in which one end and another end of each of the plurality of rigid patterns are spaced apart from each other is disposed in each corner of the lower substrate.

15. The display device according to claim 12, wherein each of the plurality of rigid patterns includes a plurality of sub patterns which is spaced apart from each other and a location in which the plurality of sub patterns is spaced apart from each other is disposed in a corner of the lower substrate.

16. The display device according to claim 9, further comprising a printed circuit board which is electrically connected to the lower substrate and is located on a rear surface of the lower substrate,
wherein each of the plurality of rigid patterns includes a plurality of sub patterns which is spaced apart from each other and a location in which the plurality of sub patterns is spaced apart from each other is disposed in an area overlapping with the printed circuit board.

17. The display device according to claim 1, wherein the rigid unit is formed of ceramic or a metal material.

18. A display device, comprising:
a lower substrate which includes an active area and a non-active area and is formed of one of conducting oxide and an oxide semiconductor;
a light emitting element in the active area disposed on the lower substrate, including a cathode;
an encapsulation substrate which covers the cathode; and
a plurality of rigid patterns which is disposed on the lower substrate and is spaced apart from each other,
wherein a first rigid pattern of the plurality of rigid patterns overlaps with an end of the cathode and a second rigid pattern of the plurality of rigid patterns overlaps with an end of the encapsulation substrate.

19. The display device according to claim 18, wherein one end and another end of the plurality of rigid patterns are spaced apart from each other and a location in which the one end and the another end of each of the plurality of rigid patterns are spaced apart from each other is disposed in each corner of the lower substrate.

20. The display device according to claim 19, wherein each of the plurality of rigid patterns includes a plurality of sub patterns which is spaced apart from each other and a location in which the plurality of sub patterns is spaced apart from each other is disposed in a corner of the lower substrate.

21. The display device according to claim 19, further comprising a printed circuit board which is electrically connected to the lower substrate and is located on a rear surface of the lower substrate,
wherein each of the plurality of rigid patterns includes a plurality of sub patterns which is spaced apart from each other and a location in which the plurality of sub patterns is spaced apart from each other is disposed in an area overlapping with the printed circuit board.

22. A display device, comprising:
a lower substrate which includes an active area including a plurality of sub pixels and a non-active area enclosing the active area and is formed of one of a conducting oxide and an oxide semiconductor;
an insulating layer disposed on the lower substrate;
a light emitting element disposed on the insulating layer including a cathode; and
an encapsulation substrate disposed on the cathode,
wherein the cathode overlaps with an end of the encapsulation substrate.

23. The display device according to claim 22, further comprising a flexible film disposed on one side of the lower substrate,
wherein the cathode overlaps with an end of the encapsulation substrate in a side portion excluding the one side of the lower substrate.

24. The display device according to claim 23, further comprising a rigid unit in the one side of the lower substrate.

25. The display device according to claim 24, wherein the rigid unit is disposed on the same layer as the lower substrate, and is in contact with an end of the lower substrate.

26. The display device according to claim 24, wherein an end of the cathode is disposed to be closer to an end of the lower substrate than an end of the encapsulation substrate.

27. The display device according to claim 24, further comprising a protection member disposed below the lower substrate.
